(19) United States
(12) Patent Application Publication
(10) Pub. No.: US 2026/0351301 A1
(43) Pub. Date: Nov. 5, 2026

(54) MEMORY DEVICE CONFIGURED TO INPUT AND OUTPUT DATA

(71) Applicant: SK hynix Inc., Icheon-si Gyeonggi-do (KR)

(72) Inventors: Su Hyun OH, Icheon-si Gyeonggi-do (KR); Min Kyu MOON, Icheon-si Gyeonggi-do (KR); Young Jun PARK, Icheon-si Gyeonggi-do (KR); Kyung Jun CHO, Icheon-si Gyeonggi-do (KR)

(73) Assignee: SK hynix Inc., Icheon-si Gyeonggi-do (KR)

(21) Appl. No.: 19/282,893

(22) Filed: Jul. 28, 2025

(30) Foreign Application Priority Data
Apr. 16, 2025 (KR) 10-2025-0049809

(51) Int. Cl. G11C 11/4076; H10B 80/00; H10W 90/00; H10W 90/20

(52) U.S. Cl. CPC G11C 11/4076; H10B 80/00; H10W 90/00; H10W 90/297; H10W 90/722; H10W 90/724

(57) ABSTRACT

A semiconductor chip includes a frequency division circuit configured to generate latch clock signals based on a command clock signal and an inverse command clock signal that are generated in synchronization with a clock signal and a command address input circuit configured to generate transfer command addresses of a first group having a second valid data window by latching a rising command address and a falling command address that are input to have a first valid data window in synchronization with latch clock signals of a first group, among the latch clock signals, and configured to generate transfer command addresses of a second group having the second valid data window by latching the rising command address and the falling command address that are input to have the first valid data window in synchronization with latch clock signals of a second group, among the latch clock signals.

### CROSS-REFERENCE TO RELATED APPLICATION

The present application claims priority under 35 U.S.C. § 119(a) to Korean Patent Application No. 10-2025-0049809, filed in the Korean Intellectual Property Office on Apr. 16, 2025, the entire contents of which application is incorporated herein by reference.

### BACKGROUND

### 1. Technical Field

The present disclosure generally relates to a memory device, and more particularly, to a memory device configured to input and output data by providing a valid data window of a command address to one or more core chips by increasing the valid data window in a base chip.

### 2. Related Art

As technology for manufacturing a semiconductor device is developed so does packaging technology for a plurality of core chips. The packaging technology is developed so that the semiconductor device can be highly integrated and perform at higher levels. In packaging technologies for implementing the semiconductor device, a technology relating to a three-dimensional (3-D) structure in which a plurality of core chips is vertically stacked out of a two-dimensional (2-D) structure in which a plurality of core chips is flatly disposed on a printed circuit board (PCB) is variously developed. The semiconductor device having the 3-D structure may be implemented by stacking a plurality of core chips through a through silicon via (TSV) (hereinafter referred to as a “through via”) like high bandwidth memory (HBM) or by stacking a plurality of core chips through wire bonding.

In general, access to a core chip may be performed through a base chip. For example, after the start of a read operation for the core chip, the base chip may transmit a command and an address to the core chip through an input and output line included in an interface area for a read operation. The core chip may receive the command and the address and transmit data stored in the core chip to the base chip. The input and output line included in the interface area is implemented with a wire causing longer loading durations, and may thus transmit the command and the address to the core chip through a separate repeater.

Furthermore, the command and the address that are input at a rising edge and falling edge of a clock signal and that have a short valid data window are transmitted to the core chip through a plurality of latch circuits in synchronization with a division clock signal. When the division clock signal is continuously generated, a margin of the plurality of latch circuits for latching the command and the address may be insufficient.

### SUMMARY

In an embodiment, a semiconductor chip may include a frequency division circuit configured to generate a plurality of latch clock signals based on a command clock signal and an inverse command clock signal that are generated in synchronization with a clock signal and a command address input circuit configured to generate transfer command addresses of a first group having a second valid data window by latching a rising command address and a falling command address that are input to have a first valid data window in synchronization with latch clock signals of a first group, among the plurality of latch clock signals, and configured to generate transfer command addresses of a second group having the second valid data window by latching the rising command address and the falling command address that are input to have the first valid data window in synchronization with latch clock signals of a second group, among the plurality of latch clock signals.

In an embodiment, a memory device may include a base chip configured to generate a rising command address and a falling command address having a first valid data window by latching an external command address in synchronization with a clock signal and an inverse clock signal that are generated from an external clock signal in an interface area, configured to generate a plurality of transfer command addresses having a second valid data window by latching the rising command address and the falling command address in synchronization with a plurality of latch clock signals that are generated based on a pulse of the inverse clock signal, and configured to output the plurality of transfer command addresses to core chips through a through via area. The core chips output data to the base chip by receiving the plurality of transfer command addresses.

### BRIEF DESCRIPTION OF THE DRAWINGS

FIG. 1 is a block diagram illustrating the construction of a memory system according to an embodiment of the present disclosure.

FIG. 2 is a block diagram illustrating the construction of a base chip according to an embodiment of the present disclosure.

FIG. 3 is a block diagram illustrating the construction of an address buffer circuit according to an embodiment of the present disclosure.

FIG. 4 is a timing diagram for describing an operation of a clock buffer circuit and the address buffer circuit according to an embodiment of the present disclosure.

FIG. 5 is a block diagram illustrating the construction of a frequency division circuit according to an embodiment of the present disclosure.

FIG. 6 is a diagram illustrating the construction of a command clock signal generation circuit according to an embodiment of the present disclosure.

FIG. 7 is a diagram illustrating the construction of a division clock signal generation circuit according to an embodiment of the present disclosure.

FIG. 8 is a block diagram illustrating the construction of a latch clock signal generation circuit according to an embodiment of the present disclosure.

FIG. 9 is a diagram illustrating the construction of an even odd sensing circuit according to an embodiment of the present disclosure.

FIG. 10 is a circuit diagram illustrating the construction of a masking circuit according to an embodiment of the present disclosure.

FIGS. 11 and 12 are timing diagrams for describing an operation of generating, by the base chip, a transfer command address based on an inverse clock signal according to an embodiment of the present disclosure.

FIGS. 13 and 14 are timing diagrams for describing an operation of generating, by the base chip, a transfer command address based on a clock signal according to an embodiment of the present disclosure.

FIG. 15 is a diagram for describing locations at which an interface area and a through via area included in the base chip according to an embodiment of the present disclosure are disposed.

### DETAILED DESCRIPTION

In the descriptions of the following embodiments, terms such as “first” and “second,” which are used to distinguish among various components, are not limited by the components. For example, a first component may be referred to as a second component, and vice versa.

When one component is referred to as being “coupled” or “connected” to another component, it should be understood that the components may be directly coupled or connected to each other or coupled or connected to each other through another component interposed therebetween. In contrast, when one component is referred to as being “directly coupled” or “directly connected” to another component, it should be understood that the components are directly coupled or connected to each other without another component interposed therebetween.

A “logic high level” and a “logic low level” are used to describe the logic levels of signals. A signal having a “logic high level” is distinguished from a signal having a “logic low level.” For example, when a signal having a first voltage corresponds to a signal having a “logic high level,” a signal having a second voltage may correspond to a signal having a “logic low level.” According to an embodiment, a “logic high level” may be set to a voltage higher than a “logic low level.” According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

Hereafter, the present disclosure will be described in more detail through embodiments. The embodiments are only used to exemplify the present disclosure, and the scope of the present disclosure is not limited by the embodiments.

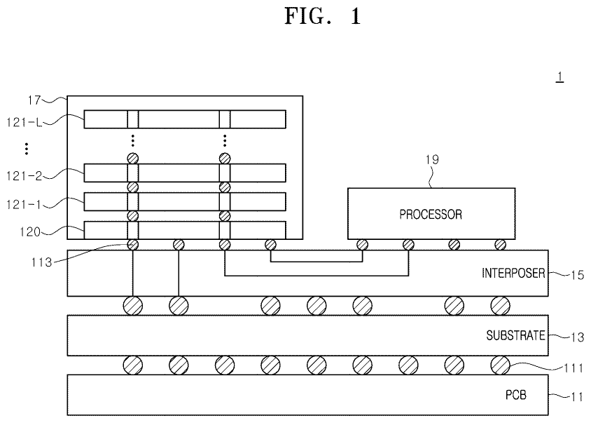

FIG. 1 is a block diagram illustrating the construction of a memory system according to an embodiment of the present disclosure. As illustrated in FIG. 1, the memory system 1 may include a printed circuit board (PCB) 11, a substrate 13, an interposer 15, a memory device 17, and a processor 19.

The PCB 11 connects several electronic components in order to form an electronic circuit (not illustrated). A copper layer, a solder mask and a silk screen may be formed on the PCB 11. A circuit path that transmits a signal or power may be formed in the copper layer. In an embodiment, the solder mask prevents or mitigates damage to the circuit and protects a specific area in which components may be soldered. Furthermore, the silk screen indicates a position or information of an electronic component in the form of characters or symbols printed on a surface of the PCB 11.

The substrate 13 is formed over the PCB 11 through bump pads (e.g., 111), and may mechanically support the interposer 15, the memory device 17, and the processor 19. The substrate 13 may be used as an insulator as a material, that is, a physical base for the PCB 11, in general. The material of the substrate 13 include flame-retardant level 4 (FR4), that is, an insulator made of glass fiber and epoxy resin, ceramics which can withstand a high temperature and is commonly used in a high frequency circuit or a high temperature environment due to its thermal conductivity, and polyimide which is used as a base material for a flexible PCB due to its flexible characteristic.

The interposer 15 is formed over the substrate 13 through bump pads, and may include wires that connect electronic components (e.g., the memory device 17 and the processor 19) with unmatched foam factors or pin arrangements. The interposer 15 may convert signals in different interfaces.

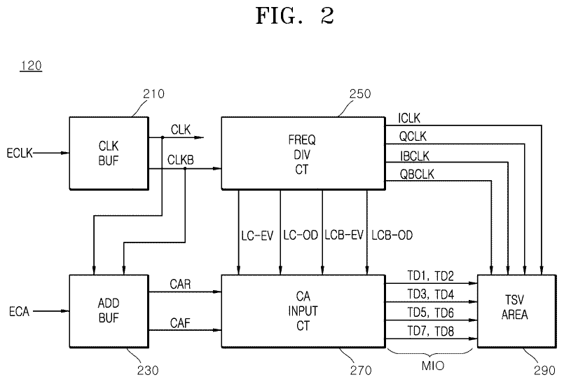

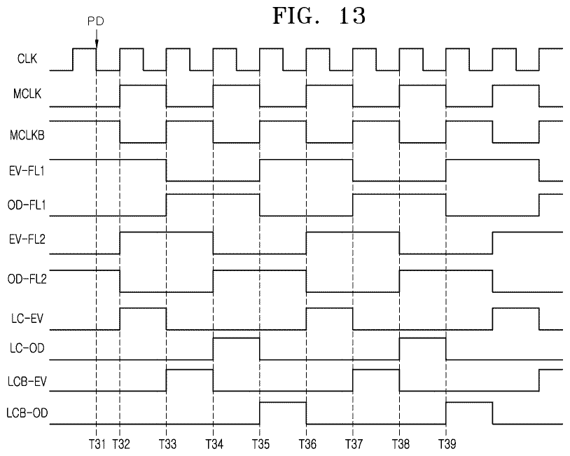

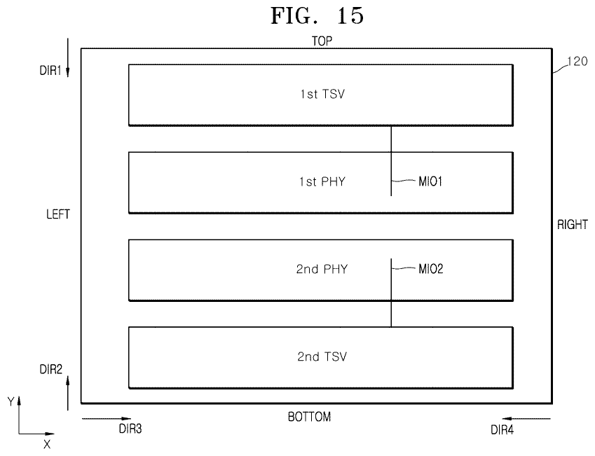

The memory device 17 may be formed over the interposer 15 through micro bump pads (e.g., 113). The memory device 17 may store data applied by the processor 19 or output data stored in the memory device 17 to the processor 19, under the control of the processor 19. The memory device 17 may include a base chip 120 and a plurality of core chips 121-1 to 121-L. The plurality of core chips 121-1 to 121-L may be stacked on or over the base chip 120 through micro bump pads. The base chip 120 and the plurality of core chips 121-1 to 121-L may be vertically connected through TSVs. The base chip 120 may generate a clock signal (CLK in FIG. 2) and an inverse clock signal (CLKB in FIG. 2) from an external clock signal (ECLK in FIG. 2). The base chip 120 may generate a rising command address (CAR in FIG. 2) and a falling command address (CAF in FIG. 2) each having a first valid data window by latching an external command address (ECA in FIG. 2) in synchronization with the clock signal (CLK in FIG. 2) and the inverse clock signal (CLKB in FIG. 2). The first valid data window of each of the rising command address (CAR in FIG. 2) and the falling command address (CAF in FIG. 2) may be set as a first cycle of the clock signal (CLK in FIG. 2) and the inverse clock signal CLKB. The base chip 120 may generate a latch clock signal (LC-EV, LC-OD, LCB-EV, and LCB-OD in FIG. 2) based on a pulse of the inverse clock signal (CLKB in FIG. 2). The base chip 120 may generate a transfer command address (TD1, TD2, TD3, TD4, TD5, TD6, TD7, and TD8 in FIG. 2) having a second valid data window by latching the rising command address (CAR in FIG. 2) and the falling command address (CAF in FIG. 2) in synchronization with the latch clock signal (LC-EV, LC-OD, LCB-EV, and LCB-OD in FIG. 2). The second valid data window of the transfer command address (TD1, TD2, TD3, TD4, TD5, TD6, TD7, and TD8 in FIG. 2) may be set as a fourth cycle of the clock signal (CLK in FIG. 2) and the inverse clock signal CLKB. The base chip 120 may generate the transfer command address (TD1, TD2, TD3, TD4, TD5, TD6, TD7, and TD8 in FIG. 2) having the second valid data window by latching the rising command address (CAR in FIG. 2) and the falling command address (CAF in FIG. 2) each having the first valid data window in an interface area (1st PHY and 2nd PHY in FIG. 15) having long loading. The base chip 120 may output the transfer command address (TD1, TD2, TD3, TD4, TD5, TD6, TD7, and TD8 in FIG. 2) to the plurality of core chips 121-1 to 121-L through a through via. The base chip 120 may output the transfer command address (TD1, TD2, TD3, TD4, TD5, TD6, TD7, and TD8 in FIG. 2) to the plurality of core chips 121-1 to 121-L through through via areas (1st TSV and 2nd TSV in FIG. 15). The base chip 120 may receive data from the plurality of core chips 121-1 to 121-L through the through via. The plurality of core chips 121-1 to 121-L may output data to the base chip 120 by receiving the transfer command address (TD1, TD2, TD3, TD4, TD5, TD6, TD7, and TD8 in FIG. 2) through the through via. The loading of the interface area (1st PHY and 2nd PHY in FIG. 13) may be set as loading longer than the loading of the through via area (1^{st} TSV and 2^{nd} TSV in FIG. 15). The external clock signal (ECLK in FIG. 2) may be set as a signal that that is periodically toggled and received from the processor 19. The external command address (ECA in FIG. 2) may be set as a signal that includes a command and an address for controlling operations of the plurality of core chips 121-1 to 121-L and that is input from the processor 19. The base chip 120 may be implemented with a component, such as a controller, a base chip, a semiconductor chip, or a semiconductor device for controlling operations of the core dies 121-1 to 121-L. The core dies 121-1 to 121-L may be implemented with a component, such as a memory device, a core chip, a semiconductor chip, or a semiconductor device that stores data and that outputs data stored in the core die.

Each of the plurality of core chips 121-1 to 121-L may include a plurality of channel areas that store data and output data stored in each channel area. Each of the plurality of channel areas may be assigned a channel that independently operates, and may receive or transmit data. Each of the plurality of channel areas may include a core area, and may receive or transmit data. The number L of core chips 121-1 to 121-L may be 4, 8, 12, or 16. For example, when each of the core chips 121-1 to 121-12 has 8 channels, each of the core chips 121-1 to 121-4, the core chips 121-5 to 121-8, and the core chips 121-9 to 121-12 includes 32 channel areas, and may transmit and receive data to and from the processor 19 in a rank unit including 32 channels. The number L of core chips 121-1 to 121-L may be greater than 16.

The processor 19 may output the external clock signal (ECLK in FIG. 2) and the external command address (ECA in FIG. 2) to the base chip 120 through a wire formed within the interposer 15. The processor 19 may receive data from the base chip 120 through a wire formed within the interposer 15. The processor 19 may control operations of the base chip 120 and the plurality of core chips 121-1 to 121-L.

FIG. 2 is a block diagram illustrating a construction of the base chip 120 according to an embodiment of the present disclosure. As illustrated in FIG. 2, the base chip 120 may include a clock buffer circuit (CLK BUF) 210, an address buffer circuit (ADD BUF) 230, a frequency division circuit (FREQ DIV CT) 250, a command address input circuit (CA INPUT CT) 270, and a through via area (TSV AREA) 290.

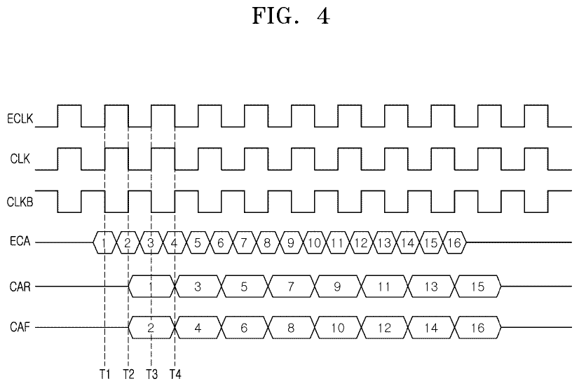

The clock buffer circuit 210 may generate the clock signal CLK and the inverse clock signal CLKB based on the external clock signal ECLK. The clock buffer circuit 210 may generate the clock signal CLK and the inverse clock signal CLKB that periodically toggle by buffering the external clock signal ECLK that periodically toggles. The clock buffer circuit 210 may generate the clock signal CLK having the same phase as the external clock signal ECLK. The clock buffer circuit 210 may generate the inverse clock signal CLKB having a phase opposite to the phase of the external clock signal ECLK. An operation of generating, by the clock buffer circuit 210, the clock signal CLK and the inverse clock signal CLKB based on the external clock signal ECLK is described later with reference to FIG. 4.

The address buffer circuit 230 may generate the rising command address CAR and the falling command address CAF based on the external command address ECA in synchronization with the clock signal CLK and the inverse clock signal CLKB. The address buffer circuit 230 may generate the rising command address CAR having the first valid data window based on the external command address ECA in synchronization with the clock signal CLK. The address buffer circuit 230 may generate the falling command address CAF having the first valid data window based on the external command address ECA in synchronization with the inverse clock signal CLKB. An operation of generating, by the address buffer circuit 230, the rising command address CAR and the falling command address CAF based on the external command address ECA in synchronization with the clock signal CLK and the inverse clock signal CLKB is described later with reference to FIG. 4.

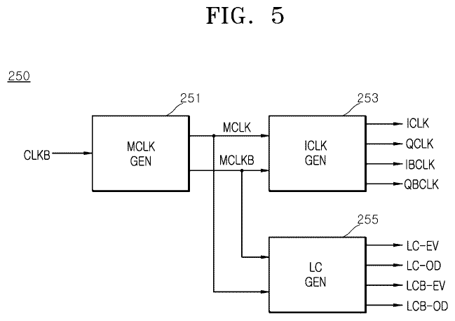

The frequency division circuit 250 may generate the first to fourth latch clock signals LC-EV, LC-OD, LCB-EV, and LCB-OD by dividing the frequency of the inverse clock signal CLKB. The frequency division circuit 250 may generate the first to fourth latch clock signals LC-EV, LC-OD, LCB-EV, and LCB-OD that are generated based on a pulse of a command clock signal (MCLK in FIG. 5) and a pulse of an inverse command clock signal (MCLKB in FIG. 5) that are generated in synchronization with the inverse clock signal CLKB. When a pulse of the command clock signal (MCLK in FIG. 5) is generated, the frequency division circuit 250 may block the generation of one of the first latch clock signal LC-EV and the second latch clock signal LC-OD. When a pulse of the inverse command clock signal (MCLKB in FIG. 5) is generated, the frequency division circuit 250 may block the generation of one of the third latch clock signal LCB-EV and the fourth latch clock signal LCB-OD. The first latch clock signal LC-EV and the third latch clock signal LCB-EV may be set as the latch clock signal of a first group. The second latch clock signal LC-OD and the fourth latch clock signal LCB-OD may be set as the latch clock signal of a second group.

The frequency division circuit 250 generates the first to fourth latch clock signals LC-EV, LC-OD, LCB-EV, and LCB-OD by dividing the frequency of the inverse clock signal CLKB. However, according to an embodiment, the frequency division circuit 250 may generate the first to fourth latch clock signals LC-EV, LC-OD, LCB-EV, and LCB-OD by dividing the frequency of the clock signal CLK.

The frequency division circuit 250 may generate first to fourth division clock signals ICLK, QCLK, IBCLK, and QBCLK by dividing the frequency of the inverse clock signal CLKB. The frequency division circuit 250 may generate the first to fourth division clock signals ICLK, QCLK, IBCLK, and QBCLK that are sequentially generated in synchronization with the inverse clock signal CLKB. The first to fourth division clock signals ICLK, QCLK, IBCLK, and QBCLK may each be generated to have a phase difference of 90°. The frequency division circuit 250 may output the first to fourth division clock signals ICLK, QCLK, IBCLK, and QBCLK to the through via area 290. The first to fourth division clock signals ICLK, QCLK, IBCLK, and QBCLK may be set as signals that latch the first to eighth transfer command addresses TD1 to TD8 within the plurality of core chips 121-1 to 121-L.

The frequency division circuit 250 generates the first to fourth division clock signals ICLK, QCLK, IBCLK, and QBCLK by dividing the frequency of the inverse clock signal CLKB. However, according to an embodiment, the frequency division circuit 250 may generate the first to fourth division clock signals ICLK, QCLK, IBCLK, and QBCLK by dividing the frequency of the clock signal CLK.

The command address input circuit 270 includes a plurality of latch circuits, and may generate the first to eighth transfer command addresses TD1 to TD8 having the second valid data window by latching the rising command address CAR and the falling command address CAF that are input to have the first valid data window through the plurality of latch circuits. The command address input circuit 270 may generate the first to eighth transfer command addresses TD1 to TD8 having the second valid data windows by latching the rising command address CAR and the falling command address CAF that are input to have the first valid data window in synchronization with the first to fourth latch clock signals LC-EV, LC-OD, LCB-EV, and LCB-OD. The command address input circuit 270 may generate the first transfer command address TD1 and the second transfer command address TD2 having the second valid data window by latching the rising command address CAR and the falling command address CAF that are input to have the first valid data window in synchronization with the first latch clock signal LC-EV. The command address input circuit 270 may generate the third transfer command address TD3 and the fourth transfer command address TD4 having the second valid data window by latching the rising command address CAR and the falling command address CAF that are input to have the first valid data window in synchronization with the third latch clock signal LCB-EV. The command address input circuit 270 may generate the fifth transfer command address TD5 and the sixth transfer command address TD6 having the second valid data window by latching the rising command address CAR and the falling command address CAF that are input to have the first valid data window in synchronization with the second latch clock signal LC-OD. The command address input circuit 270 may generate the seventh transfer command address TD7 and the eighth transfer command address TD8 having the second valid data window by latching the rising command address CAR and the falling command address CAF that are input to have the first valid data window in synchronization with the fourth latch clock signal LCB-OD. The command address input circuit 270 may output the first to eighth transfer command addresses TD1 to TD8 to the through via area 290 through a command input and output line MIO. The first to eighth transfer command addresses TD1 to TD8 may each be set as a signal including a command and an address that control operations of the plurality of core chips 121-1 to 121-L. The command input and output line MIO may be implemented with a wire having long loading, and may be implemented with a plurality of wires. In an embodiment, a wire having long loading may be referred to as a heavily loaded wire or long-loaded wire. The first to fourth transfer command addresses TD1 to TD4 may be set as the transfer command addresses of a first group. The fifth to eighth transfer command addresses TD5 to TD8 may be set as the transfer command addresses of a second group.

The through via area 290 may be implemented with an area including a plurality of through vias. The through via area 290 may output the first to eighth transfer command addresses TD1 to TD8 to the plurality of core chips 121-1 to 121-L through the plurality of through vias. The through via area 290 may output the first to fourth division clock signals ICLK, QCLK, IBCLK, and QBCLK to the plurality of core chips 121-1 to 121-L through the plurality of through vias. The through via area 290 may output or receive data to or from the plurality of core chips 121-1 to 121-L through the plurality of through vias.

The clock buffer circuit 210, the address buffer circuit 230, the frequency division circuit 250, and the command address input circuit 270 illustrated in FIG. 2 may be included in the interface area (1^{st} PHY and 2^{nd} PHY in FIG. 13). The through via area 290 may be included in the through via area (1^{st} TSV and 2^{nd} TSV in FIG. 13).

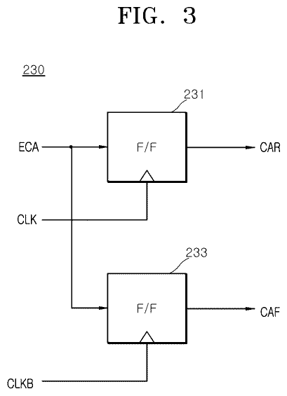

FIG. 3 is a block diagram illustrating a construction of the address buffer circuit 230 according to an embodiment of the present disclosure. As illustrated in FIG. 3, the address buffer circuit 230 may include flip-flops (F/F) 231 and 233.

The flip-flop 231 may generate the rising command address CAR based on the external command address ECA in synchronization with the clock signal CLK. The flip-flop 231 may latch the external command address ECA when the level of a pulse of the clock signal CLK transitions from a logic low level to a logic high level. The flip-flop 231 may output the external command address ECA that is latched when the level of a pulse of the clock signal CLK transitions from a logic high level to a logic low level as the rising command address CAR.

The flip-flop 233 may generate the falling command address CAF based on the external command address ECA in synchronization with the inverse clock signal CLKB. The flip-flop 233 may latch the external command address ECA when the level of a pulse of the inverse clock signal CLKB transitions from a logic low level to a logic high level. The flip-flop 233 may output the external command address ECA that is latched when the level of a pulse of the inverse clock signal CLKB transitions from a logic low level to a logic high level as the falling command address CAF.

FIG. 4 is a timing diagram for describing an operation of the clock buffer circuit 210 and the address buffer circuit 230 according to an embodiment of the present disclosure.

An operation of generating, by the clock buffer circuit 210, the clock signal CLK and the inverse clock signal CLKB based on the external clock signal ECLK is described as follows with reference to FIG. 4.

At timing T1, the clock buffer circuit 210 may generate the clock signal CLK having the same phase as the external clock signal ECLK by buffering the external clock signal ECLK that periodically toggles.

At timing T1, the clock buffer circuit 210 may generate the inverse clock signal CLKB having a phase opposite to the phase of the external clock signal ECLK by buffering the external clock signal ECLK that periodically toggles.

An operation of generating, by the address buffer circuit 230, the rising command address CAR and the falling command address CAF based on the external command address ECA in synchronization with the clock signal CLK and the inverse clock signal CLKB is described as follows with reference to FIG. 4.

In an embodiment, the external command address ECA may be input to include first to sixteenth bits that are sequentially input to the address buffer circuit 230. The valid data window of the external command address ECA may be set as a cycle that is ½ of the cycle of the clock signal CLK and the inverse clock signal CLKB.

At timing T1, the flip-flop 231 of the address buffer circuit 230 may latch the first bit ECA<1> of the external command address ECA when the level of a pulse of the clock signal CLK transitions from a logic low level to a logic high level.

At timing T2, the flip-flop 231 of the address buffer circuit 230 may output the first bit ECA<1> of the external command address ECA that is latched when the level of a pulse of the clock signal CLK transitions from a logic high level to a logic low level as the rising command address CAR.

At timing T2, the flip-flop 233 of the address buffer circuit 230 may latch the second bit ECA<2> of the external command address when the level of a pulse of the inverse clock signal CLKB transitions from a logic low level to a logic high level. The flip-flop 233 of the address buffer circuit 230 may output the second bit ECA<2> of the external command address that is latched when the level of a pulse of the inverse clock signal CLKB transitions from a logic low level to a logic high level as the falling command address CAF.

At timing T3, the flip-flop 231 of the address buffer circuit 230 may latch the third bit ECA<3> of the external command address ECA when the level of a pulse of the clock signal CLK transitions from a logic low level to a logic high level.

At timing T4, the flip-flop 231 of the address buffer circuit 230 may output the third bit ECA<4> of the external command address that is latched when the level of a pulse of the clock signal CLK transitions from a logic high level to a logic low level as the rising command address CAR.

At timing T4, the flip-flop 233 of the address buffer circuit 230 may latch the fourth bit ECA<4> of the external command address when the level of a pulse of the inverse clock signal CLKB transitions from a logic low level to a logic high level. The flip-flop 233 of the address buffer circuit 230 may output the fourth bit ECA<4> of the external command address that is latched when the level of a pulse of the inverse clock signal CLKB transitions from a logic low level to a logic high level as the falling command address CAF.

The first valid data window of the rising command address CAR may be set as the first cycle of the clock signal CLK and the inverse clock signal CLKB. The first valid data window of the falling command address CAF may be set as the first cycle of the clock signal CLK and the inverse clock signal CLKB.

In this case, an operation of generating the rising command address CAR and the falling command address CAF from the fifth to sixteenth ECA<5:16> of the external command address is the same as an operation of generating the rising command address CAR and the falling command address CAF from the first to fourth bits ECA<1:4> of the external command address, and thus a detailed description thereof is omitted.

FIG. 5 is a block diagram illustrating a construction of the frequency division circuit 250 according to an embodiment of the present disclosure. As illustrated in FIG. 5, the frequency division circuit 250 may include a command clock signal generation circuit (MCLK GEN) 251, a division clock signal generation circuit (ICLK GEN) 253, and a latch clock signal generation circuit (LC GEN) 255.

The command clock signal generation circuit 251 may generate the command clock signal MCLK and the inverse command clock signal MCLKB that are generated in synchronization with the inverse clock signal CLKB. The command clock signal generation circuit 251 may generate the command clock signal MCLK and the inverse command clock signal MCLKB that are initialized after the start of a power-down operation. The command clock signal generation circuit 251 may generate the command clock signal MCLK and the inverse command clock signal MCLKB by dividing the frequency of the inverse clock signal CLKB after a power-down operation. The command clock signal generation circuit 251 may generate the command clock signal MCLK the level of which transitions when the level of a pulse of the inverse clock signal CLKB transitions from a logic low level to a logic high level. The command clock signal generation circuit 251 may generate the inverse command clock signal MCLKB the level of which transitions when the level of a pulse of the inverse clock signal CLKB transitions from a logic low level to a logic high level. The command clock signal generation circuit 251 may generate the command clock signal MCLK and the inverse command clock signal MCLKB having opposite phases when the level of a pulse of the inverse clock signal CLKB transitions from a logic low level to a logic high level. The power-down operation may be set as an operation that is not performed because power to the memory device 17 is blocked.

The division clock signal generation circuit 253 may generate the first to fourth division clock signals ICLK, QCLK, IBCLK, and QBCLK by dividing the frequencies of the command clock signal MCLK and the inverse command clock signal MCLKB. The division clock signal generation circuit 253 may generate the first to fourth division clock signals ICLK, QCLK, IBCLK, and QBCLK that are sequentially generated in synchronization with the command clock signal MCLK and the inverse command clock signal MCLKB. The first to fourth division clock signals ICLK, QCLK, IBCLK, and QBCLK may each be generated to have a phase difference of 90°. The division clock signal generation circuit 253 may output the first to fourth division clock signals ICLK, QCLK, IBCLK, and QBCLK to the through via area 290.

The latch clock signal generation circuit 255 may generate the first to fourth latch clock signals LC-EV, LC-OD, LCB-EV, and LCB-OD that are generated based on a pulse of the command clock signal MCLK and a pulse of the inverse command clock signal MCLKB. The latch clock signal generation circuit 255 may generate one of the first latch clock signal LC-EV and the second latch clock signal LC-OD when a pulse of the command clock signal MCLK having a logic high level is generated. The latch clock signal generation circuit 255 may block the generation of one of the first latch clock signal LC-EV and the second latch clock signal LC-OD when a pulse of the command clock signal MCLK having a logic high level is generated. The latch clock signal generation circuit 255 may generate one of the third latch clock signal LCB-EV and the fourth latch clock signal LCB-OD when a pulse of the inverse command clock signal MCLKB having a logic high level is generated. The latch clock signal generation circuit 255 may block the generation of one of the third latch clock signal LCB-EV and the fourth latch clock signal LCB-OD when a pulse of the inverse command clock signal MCLKB having a logic high level is generated.

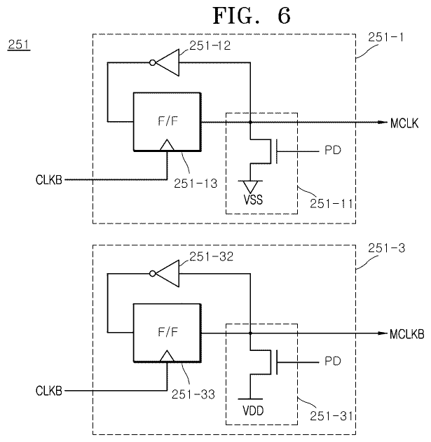

FIG. 6 is a diagram illustrating a construction of the command clock signal generation circuit 251 according to an embodiment of the present disclosure. As illustrated in FIG. 6, the command clock signal generation circuit 251 may include a first command clock signal generation circuit 251-1 and a second command clock signal generation circuit 251-3.

The first command clock signal generation circuit 251-1 may include a first initialization circuit 251-11, an inverter 251-12, and a flip-flop (F/F) 251-13. The first initialization circuit 251-11 may generate the command clock signal MCLK that is initialized to have a first logic level (a logic low level) when a power-down signal PD is enabled to a logic high level. The first initialization circuit 251-11 may initialize the command clock signal MCLK to a logic low level (the first logic level) by driving the command clock signal MCLK with a ground voltage VSS when the power-down signal PD is enabled to a logic high level. The inverter 251-12 may invert and output the command clock signal MCLK. The flip-flop 251-13 may generate the command clock signal MCLK by latching the output signal of the inverter 251-12 when the level of a pulse of the inverse clock signal CLKB transitions from a logic low level to a logic high level. The first command clock signal generation circuit 251-1 may generate the command clock signal MCLK that is initialized to have a logic low level (the first logic level) by the power-down signal PD. The first command clock signal generation circuit 251-1 may generate the command clock signal MCLK when the level of a pulse of the inverse clock signal CLKB transitions from a logic low level to a logic high level. As such, the first command clock signal generation circuit 251-1 generates the command clock signal MCLK that toggles in synchronization with the inverse clock signal CLKB. The power-down signal PD may be set as a signal that is enabled to a logic high level after the start of a power-down operation.

The second command clock signal generation circuit 251-3 may include a second initialization circuit 251-31, an inverter 251-32, and a flip-flop (F/F) 251-33. The second initialization circuit 251-31 may generate the inverse command clock signal MCLKB that is initialized to have a logic high level (a second logic level) when the power-down signal PD is enabled to a logic high level. The second initialization circuit 251-31 may initialize the inverse command clock signal MCLKB to a logic high level (the second logic level) by driving the inverse command clock signal MCLKB with a power supply voltage VDD when the power-down signal PD is enabled to a logic high level. The inverter 251-32 may invert and output the inverse command clock signal MCLKB. The flip-flop 251-33 may generate the inverse command clock signal MCLKB by latching the output signal of the inverter 251-32 when the level of a pulse of the inverse clock signal CLKB transitions from a logic low level to a logic high level. The second command clock signal generation circuit 251-3 may generate the inverse command clock signal MCLKB that is initialized to a logic high level (the second logic level) by the power-down signal PD. The second command clock signal generation circuit 251-3 may generate the inverse command clock signal MCLKB the level of which transitions when the level of a pulse of the inverse clock signal CLKB transitions from a logic low level to a logic high level. As such, the second command clock signal generation circuit 251-3 generates the inverse command clock signal MCLKB that toggles in synchronization with the inverse clock signal CLKB.

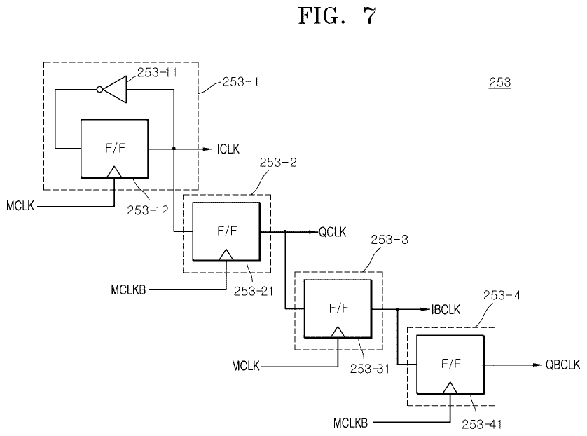

FIG. 7 is a diagram illustrating a construction of the division clock signal generation circuit 253 according to an embodiment of the present disclosure. The division clock signal generation circuit 253 may include a first division clock generation circuit 253-1, a second division clock generation circuit 253-2, a third division clock generation circuit 253-3, and a fourth division clock generation circuit 253-4.

The first division clock generation circuit 253-1 may include an inverter 253-11 and a flip-flop (F/F) 253-12. The inverter 253-11 may invert and output the first division clock signal ICLK. The flip-flop 253-12 may latch the output signal of the inverter 253-11 when the level of the command clock signal MCLK transitions from a logic low level to a logic high level. The flip-flop 253-12 may output the output signal of the inverter 253-11 that is latched when the level of the command clock signal MCLK transitions from a logic low level to a logic high level as the first division clock signal ICLK. The first division clock generation circuit 253-1 may generate the first division clock signal ICLK the level of which transitions whenever the level of the command clock signal MCLK transitions from a logic low level to a logic high level.

The second division clock generation circuit 253-2 may include a flip-flop (F/F) 253-21. The flip-flop 253-21 may latch the first division clock signal ICLK when the level of the inverse command clock signal MCLKB transitions from a logic low level to a logic high level. The flip-flop 253-21 may output the first division clock signal ICLK that is latched when the level of the inverse command clock signal MCLKB transitions from a logic low level to a logic high level as the second division clock signal QCLK. The second division clock generation circuit 253-2 may generate the second division clock signal QCLK the level of which transitions whenever the level of the inverse command clock signal MCLKB transitions from a logic low level to a logic high level.

The third division clock generation circuit 253-3 may include a flip-flop (F/F) 253-31. The flip-flop 253-31 may latch the second division clock signal QCLK when the level of the command clock signal MCLK transitions from a logic low level to a logic high level. The flip-flop 253-31 may output the second division clock signal QCLK that is latched when the level of the command clock signal MCLK transitions from a logic low level to a logic high level as the third division clock signal IBCLK. The third division clock generation circuit 253-3 may generate the third division clock signal IBCLK the level of which transitions whenever the level of the command clock signal MCLK transitions from a logic low level to a logic high level.

The fourth division clock generation circuit 253-4 may include a flip-flop (F/F) 253-41. The flip-flop 253-41 may latch the third division clock signal IBCLK when the level of the inverse command clock signal MCLKB transitions from a logic low level to a logic high level. The flip-flop 253-41 may output the third division clock signal IBCLK that is latched when the level of the inverse command clock signal MCLKB transitions from a logic low level to a logic high level as the fourth division clock signal QBCLK. The fourth division clock generation circuit 253-4 may generate the fourth division clock signal QBCLK the level of which transitions whenever the level of the inverse command clock signal MCLKB transitions from a logic low level to a logic high level.

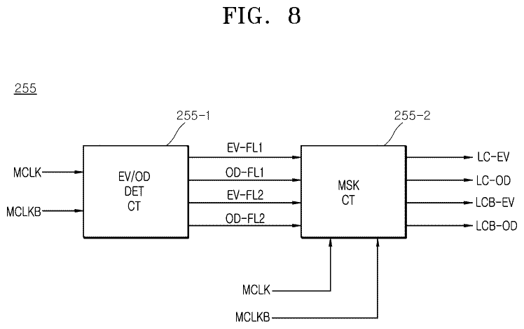

FIG. 8 is a block diagram illustrating a construction of the latch clock signal generation circuit 255 according to an embodiment of the present disclosure. The latch clock signal generation circuit 255 may include an even odd sensing circuit (EV/OD DET CT) 255-1 and a masking circuit (MAK CT) 255-2.

The even odd sensing circuit 255-1 may generate first and second even flag signals EV-FL1 and EV-FL2 and first and second odd flag signals OD-FL1 and OD-FL2 by detecting timing at which a pulse of the command clock signal MCLK and a pulse of the inverse command clock signal MCLKB are input.

The even odd sensing circuit 255-1 may generate the first even flag signal EV-FL1 and the first odd flag signal OD-FL1 that are generated based on a pulse of the command clock signal MCLK. The even odd sensing circuit 255-1 may generate the first even flag signal EV-FL1 the level of which transitions when the level of a pulse of the command clock signal MCLK transitions from a logic high level to a logic low level. The even odd sensing circuit 255-1 may generate the first odd flag signal OD-FL1 the level of which transitions when the level of a pulse of the command clock signal MCLK transitions from a logic high level to a logic low level.

The even odd sensing circuit 255-1 may generate the second even flag signal EV-FL2 and the second odd flag signal OD-FL2 that are generated based on a pulse of the inverse command clock signal MCLKB. The even odd sensing circuit 255-1 may generate the second even flag signal EV-FL2 the level of which transitions when the level of a pulse of the inverse command clock signal MCLKB transitions from a logic high level to a logic low level. The even odd sensing circuit 255-1 may generate the second odd flag signal OD-FL2 the level of which transitions when the level of a pulse of the inverse command clock signal MCLKB transitions from a logic high level to a logic low level.

The masking circuit 255-2 may generate the first to fourth latch clock signals LC-EV, LC-OD, LCB-EV, and LCB-OD based on logic levels of the first and second even flag signals EV-FL1 and EV-FL2 and logic levels of the first and second odd flag signals OD-FL1 and OD-FL2 when a pulse of the command clock signal MCLK and a pulse of the inverse command clock signal MCLKB are generated.

The masking circuit 255-2 may generate the first latch clock signal LC-EV having a logic high level when a pulse of the command clock signal MCLK having a logic high level is generated and the first even flag signal EV-FL1 having a logic high level is generated. The masking circuit 255-2 may generate the first latch clock signal LC-EV having a logic low level when a pulse of the command clock signal MCLK having a logic high level is generated and the first even flag signal EV-FL1 having a logic low level is generated. The masking circuit 255-2 may block the generation of the first latch clock signal LC-EV when a pulse of the command clock signal MCLK having a logic high level is generated and the first even flag signal EV-FL1 having a logic low level is generated.

The masking circuit 255-2 may generate the second latch clock signal LC-OD having a logic high level when a pulse of the command clock signal MCLK having a logic high level is generated and the first odd flag signal OD-FL1 having a logic high level is generated. The masking circuit 255-2 may generate the second latch clock signal LC-OD having a logic low level when a pulse of the command clock signal MCLK having a logic high level is generated and the first odd flag signal OD-FL1 having a logic low level is generated. The masking circuit 255-2 may block the generation of the second latch clock signal LC-OD when a pulse of the command clock signal MCLK having a logic high level is generated and the first odd flag signal OD-FL1 having a logic low level is generated.

The masking circuit 255-2 may generate the third latch clock signal LCB-EV having a logic high level when a pulse of the inverse command clock signal MCLKB having a logic high level is generated and the second even flag signal EV-FL2 having a logic high level is generated. The masking circuit 255-2 may generate the third latch clock signal LCB-EV having a logic low level when a pulse of the inverse command clock signal MCLKB having a logic high level is generated and the second even flag signal EV-FL2 having a logic low level is generated. The masking circuit 255-2 may block the generation of the third latch clock signal LCB-EV when a pulse of the inverse command clock signal MCLKB having a logic high level is generated and the second even flag signal EV-FL2 having a logic low level is generated.

The masking circuit 255-2 may generate the fourth latch clock signal LCB-OD having a logic high level when a pulse of the inverse command clock signal MCLKB having a logic high level is generated and the second odd flag signal OD-FL2 having a logic high level is generated. The masking circuit 255-2 may generate the fourth latch clock signal LCB-OD having a logic low level when a pulse of the inverse command clock signal MCLKB having a logic high level is generated and the second odd flag signal OD-FL2 having a logic low level is generated. The masking circuit 255-2 may block the generation of the fourth latch clock signal LCB-OD when a pulse of the inverse command clock signal MCLKB having a logic high level is generated and the second odd flag signal OD-FL2 having a logic low level is generated.

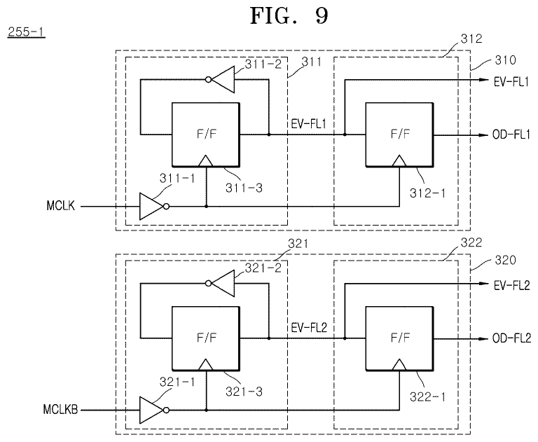

FIG. 9 is a diagram illustrating a construction of the even odd sensing circuit 255-1 according to an embodiment of the present disclosure. The even odd sensing circuit 255-1 may include a first flag signal generation circuit 310 and a second flag signal generation circuit 320.

The first flag signal generation circuit 310 may include a first even sensing circuit 311 and a first odd sensing circuit 312. The first even sensing circuit 311 may be implemented with inverters 311-1 and 311-2 and a flip-flop (F/F) 311-3. The first even sensing circuit 311 may generate the first even flag signal EV-FL1 that toggles when a pulse of the command clock signal MCLK having a logic low level (the first logic level) is generated. The first even flag signal EV-FL1 may be set as a signal that is initialized as a logic high level. The first odd sensing circuit 312 may be implemented with a flip-flop (F/F) 312-1. The first odd sensing circuit 312 may latch the first even flag signal EV-FL1. The first odd sensing circuit 312 may output the first even flag signal EV-FL1 that is latched when a pulse of the command clock signal MCLK having a logic low level (the first logic level) is generated as the first odd flag signal OD-FL1. The first odd sensing circuit 312 may generate the first odd flag signal OD-FL1 that toggles when a pulse of the command clock signal MCLK having a logic low level (the first logic level) is generated. The first odd flag signal OD-FL1 may be set as a signal that is initialized as a logic low level. The first flag signal generation circuit 310 may generate the first even flag signal EV-FL1 and the first odd flag signal OD-FL1 that toggle when a pulse of the command clock signal MCLK having a logic low level (the first logic level) is generated.

The second flag signal generation circuit 320 may include a second even sensing circuit 321 and a second odd sensing circuit 322. The second even sensing circuit 321 may be implemented with inverters 321-1 and 321-2 and a flip-flop (F/F) 321-3. The second even sensing circuit 321 may generate the second even flag signal EV-FL2 that toggles when a pulse of the inverse command clock signal MCLKB having a logic low level (the first logic level) is generated. The second even flag signal EV-FL2 may be set as a signal that is initialized as a logic low level. The second odd sensing circuit 322 may be implemented with a flip-flop (F/F) 322-1. The second odd sensing circuit 322 may latch the second even flag signal EV-FL2. The second odd sensing circuit 322 may output the second even flag signal EV-FL2 that is latched when a pulse of the inverse command clock signal MCLKB having a logic low level (the first logic level) is generated as the second odd flag signal OD-FL2. The second odd sensing circuit 322 may generate the second odd flag signal OD-FL2 that toggles when a pulse of the inverse command clock signal MCLKB having a logic low level (the first logic level) is generated. The second odd flag signal OD-FL2 may be set as a signal that is initialized as a logic low level. The second flag signal generation circuit 320 may generate the second even flag signal EV-FL2 and the second odd flag signal OD-FL2 that toggle when a pulse of the inverse command clock signal MCLKB having a logic low level (the first logic level) is generated.

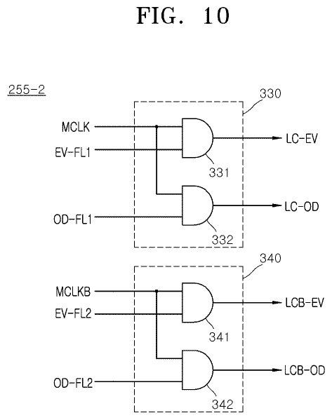

FIG. 10 is a circuit diagram illustrating a construction of the masking circuit 255-2 according to an embodiment of the present disclosure. The masking circuit 255-2 may include a first logic circuit 330 and a second logic circuit 340.

The first logic circuit 330 may be implemented with AND gates 331 and 332. The AND gate 331 may generate the first latch clock signal LC-EV by performing an AND operation on the command clock signal MCLK and the first even flag signal EV-FL1. The AND gate 331 may generate the first latch clock signal LC-EV based on the logic level of the command clock signal MCLK and the logic level of the first even flag signal EV-FL1. The AND gate 332 may generate the second latch clock signal LC-OD by performing an AND operation on the command clock signal MCLK and the first odd flag signal OD-FL1. The AND gate 332 may generate the second latch clock signal LC-OD based on the logic level of the command clock signal MCLK and the logic level of the first odd flag signal OD-FL1.

The first logic circuit 330 may generate the first latch clock signal LC-EV having a logic high level when a pulse of the command clock signal MCLK having a logic high level is generated and the first even flag signal EV-FL1 having a logic high level is generated. The first logic circuit 330 may generate the first latch clock signal LC-EV having a logic low level when a pulse of the command clock signal MCLK having a logic high level is generated and the first even flag signal EV-FL1 having a logic low level is generated. The first logic circuit 330 may block the generation of the first latch clock signal LC-EV when a pulse of the command clock signal MCLK having a logic high level is generated and the first even flag signal EV-FL1 having a logic low level is generated. The first logic circuit 330 may generate the second latch clock signal LC-OD having a logic high level when a pulse of the command clock signal MCLK having a logic high level is generated and the first odd flag signal OD-FL1 having a logic high level is generated. The first logic circuit 330 may generate the second latch clock signal LC-OD having a logic low level when a pulse of the command clock signal MCLK having a logic high level is generated and the first odd flag signal OD-FL1 having a logic low level is generated. The first logic circuit 330 may block the generation of the second latch clock signal LC-OD when a pulse of the command clock signal MCLK having a logic high level is generated and the first odd flag signal OD-FL1 having a logic low level is generated.

The second logic circuit 340 may be implemented with AND gates 341 and 342. The AND gate 341 may generate the third latch clock signal LCB-EV by performing an AND operation on the inverse command clock signal MCLKB and the second even flag signal EV-FL2. The AND gate 341 may generate the third latch clock signal LCB-EV based on the logic level of the inverse command clock signal MCLKB and the logic level of the second even flag signal EV-FL2. The AND gate 342 may generate the fourth latch clock signal LCB-OD by performing an AND operation on the inverse command clock signal MCLKB and the second odd flag signal OD-FL2. The AND gate 342 may generate the fourth latch clock signal LCB-OD based on the logic level of the inverse command clock signal MCLKB and the logic level of the second odd flag signal OD-FL2.

The second logic circuit 340 may generate the third latch clock signal LCB-EV having a logic high level when a pulse of the inverse command clock signal MCLKB having a logic high level is generated and the second even flag signal EV-FL2 having a logic high level is generated. The second logic circuit 340 may generate the third latch clock signal LCB-EV having a logic low level when a pulse of the inverse command clock signal MCLKB having a logic high level is generated and the second even flag signal EV-FL2 having a logic low level is generated. The second logic circuit 340 may block the generation of the third latch clock signal LCB-EV when a pulse of the inverse command clock signal MCLKB having a logic high level is generated and the second even flag signal EV-FL2 having a logic low level is generated. The second logic circuit 340 may generate the fourth latch clock signal LCB-OD having a logic high level when a pulse of the inverse command clock signal MCLKB having a logic high level is generated and the second odd flag signal OD-FL2 having a logic high level is generated. The second logic circuit 340 may generate the fourth latch clock signal LCB-OD having a logic low level when a pulse of the inverse command clock signal MCLKB having a logic high level is generated and the second odd flag signal OD-FL2 having a logic low level is generated. The second logic circuit 340 may block the generation of the fourth latch clock signal LCB-OD when a pulse of the inverse command clock signal MCLKB having a logic high level is generated and the second odd flag signal OD-FL2 having a logic low level is generated.

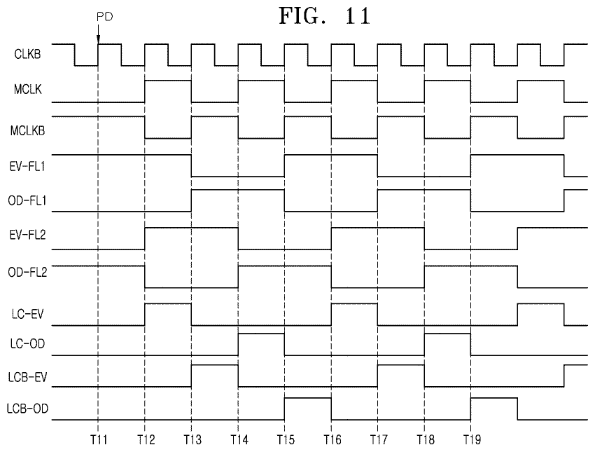

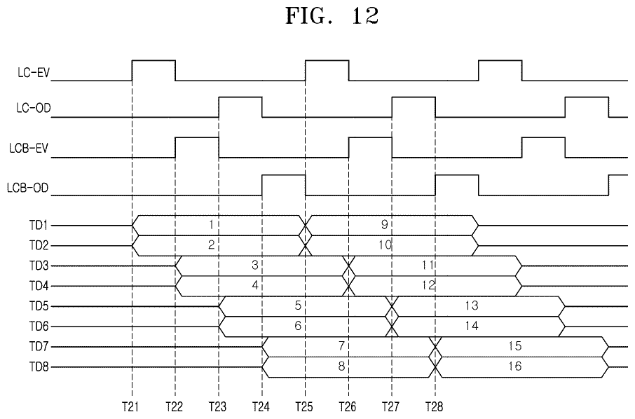

An operation of generating the first to eighth transfer command addresses TD1 to TD8 having the second valid data window by increasing the first valid data window of the rising command address CAR and the valid data window of the falling command address CAF by the inverse clock signal CLKB in the interface area of the base chip 120 having long loading according to an embodiment of the present disclosure is described as follows as an example with reference to FIGS. 11 and 12.

First, an operation of generating the first to fourth latch clock signals LC-EV, LC-OD, LCB-EV, and LCB-OD based on a pulse of the inverse clock signal CLKB in the interface area is described with reference to FIG. 11.

At timing T11, the first command clock signal generation circuit 251-1 of the command clock signal generation circuit 251 generates the command clock signal MCLK that is initialized as a logic low level (the first logic level) after the start of a power-down operation PD. The second command clock signal generation circuit 251-3 of the command clock signal generation circuit 251 generates the inverse command clock signal MCLKB that is initialized as a logic high level (the second logic level) after the start of the power-down operation PD.

At timing T12, the first command clock signal generation circuit 251-1 of the command clock signal generation circuit 251 generates the command clock signal MCLK the level of a pulse of which transitions from a logic low level to a logic high level when the level of a pulse of the inverse clock signal CLKB transitions from a logic low level to a logic high level. The second command clock signal generation circuit 251-3 of the command clock signal generation circuit 251 generates the inverse command clock signal MCLKB the level of a pulse of which transitions from a logic high level to a logic low level when the level of a pulse of the inverse clock signal CLKB transitions from a logic low level to a logic high level.

The second flag signal generation circuit 320 of the even odd sensing circuit 255-1 generates the second even flag signal EV-FL2 the level of which transitions from a logic low level to a logic high level when the level of a pulse of the inverse command clock signal MCLKB transitions from a logic high level to a logic low level.

The first logic circuit 330 of the masking circuit 255-2 generates the first latch clock signal LC-EV having a logic high level when a pulse of the command clock signal MCLK having a logic high level is generated and the first even flag signal EV-FL1 having a logic high level is generated. The first logic circuit 330 generates the second latch clock signal LC-OD having a logic low level when a pulse of the command clock signal MCLK having a logic high level is generated and the first odd flag signal OD-FL1 having a logic low level is generated. The first logic circuit 330 blocks the generation of the second latch clock signal LC-OD when a pulse of the command clock signal MCLK having a logic high level is generated and the first odd flag signal OD-FL1 having a logic low level is generated.

At timing T13, the first command clock signal generation circuit 251-1 of the command clock signal generation circuit 251 generates the command clock signal MCLK the level of a pulse of which transitions from a logic high level to a logic low level when the level of a pulse of the inverse clock signal CLKB transitions from a logic low level to a logic high level. The second command clock signal generation circuit 251-3 of the command clock signal generation circuit 251 generates the inverse command clock signal MCLKB the level of a pulse of which transitions from a logic low level to a logic high level when the level of a pulse of the inverse clock signal CLKB transitions from a logic low level to a logic high level.

The first flag signal generation circuit 310 of the even odd sensing circuit 255-1 generates the first even flag signal EV-FL1 the level of which transitions from a logic high level to a logic low level when the level of a pulse of the command clock signal MCLK transitions from a logic high level to a logic low level. The first flag signal generation circuit 310 generates the first odd flag signal OD-FL1 the level of which transitions from a logic low level to a logic high level when the level of a pulse of the command clock signal MCLK transitions from a logic high level to a logic low level.

The second logic circuit 340 of the masking circuit 255-2 generates the third latch clock signal LCB-EV having a logic high level when a pulse of the inverse command clock signal MCLKB having a logic high level is generated and the second even flag signal EV-FL2 having a logic high level is generated. The second logic circuit 340 generates the fourth latch clock signal LCB-OD having a logic low level when a pulse of the inverse command clock signal MCLKB having a logic high level is generated and the second odd flag signal OD-FL2 having a logic low level is generated. The second logic circuit 340 blocks the generation of the fourth latch clock signal LCB-OD when a pulse of the inverse command clock signal MCLKB having a logic high level is generated and the second odd flag signal OD-FL2 having a logic low level is generated.

At timing T14, the first command clock signal generation circuit 251-1 of the command clock signal generation circuit 251 generates the command clock signal MCLK the level of a pulse of which transitions from a logic low level to a logic high level when the level of a pulse of the inverse clock signal CLKB transitions from a logic low level to a logic high level. The second command clock signal generation circuit 251-3 of the command clock signal generation circuit 251 generates the inverse command clock signal MCLKB the level of a pulse of which transitions from a logic high level to a logic low level when the level of a pulse of the inverse clock signal CLKB transitions from a logic low level to a logic high level.

The second flag signal generation circuit 320 of the even odd sensing circuit 255-1 generates the second even flag signal EV-FL2 the level of which transitions from a logic high level to a logic low level when the level of a pulse of the inverse command clock signal MCLKB transitions from a logic high level to a logic low level. The second flag signal generation circuit 320 generates the second odd flag signal OD-FL2 the level of which transitions from a logic low level to a logic high level when the level of a pulse of the inverse command clock signal MCLKB transitions from a logic high level to a logic low level.

The first logic circuit 330 of the masking circuit 255-2 generates the second latch clock signal LC-OD having a logic high level when a pulse of the command clock signal MCLK having a logic high level is generated and the first odd flag signal OD-FL1 having a logic high level is generated. The first logic circuit 330 generates the first latch clock signal LC-EV having a logic low level when a pulse of the command clock signal MCLK having a logic high level is generated and the first even flag signal EV-FL1 having a logic low level is generated. The first logic circuit 330 blocks the generation of the first latch clock signal LC-EV when a pulse of the command clock signal MCLK having a logic high level is generated and the first even flag signal EV-FL1 having a logic low level is generated.

At timing T15, the first command clock signal generation circuit 251-1 of the command clock signal generation circuit 251 generates the command clock signal MCLK the level of a pulse of which transitions from a logic high level to a logic low level when the level of a pulse of the inverse clock signal CLKB transitions from a logic low level to a logic high level. The second command clock signal generation circuit 251-3 of the command clock signal generation circuit 251 generates the inverse command clock signal MCLKB the level of a pulse of which transitions from a logic low level to a logic high level when the level of a pulse of the inverse clock signal CLKB transitions from a logic low level to a logic high level.

The first flag signal generation circuit 310 of the even odd sensing circuit 255-1 generates the first even flag signal EV-FL1 the level of which transitions from a logic low level to a logic high level when the level of a pulse of the command clock signal MCLK transitions from a logic high level to a logic low level. The first flag signal generation circuit 310 generates the first odd flag signal OD-FL1 the level of which transitions from a logic high level to a logic low level when the level of a pulse of the command clock signal MCLK transitions from a logic high level to a logic low level.

The second logic circuit 340 of the masking circuit 255-2 generates the fourth latch clock signal LCB-OD having a logic high level when a pulse of the inverse command clock signal MCLKB having a logic high level is generated and the second odd flag signal OD-FL2 having a logic high level is generated. The second logic circuit 340 generates the third latch clock signal LCB-EV having a logic low level when a pulse of the inverse command clock signal MCLKB having a logic high level is generated and the second even flag signal EV-FL2 having a logic low level is generated. The second logic circuit 340 blocks the generation of the third latch clock signal LCB-EV when a pulse of the inverse command clock signal MCLKB having a logic high level is generated and the second even flag signal EV-FL2 having a logic low level is generated.

At timing T16, the first command clock signal generation circuit 251-1 of the command clock signal generation circuit 251 generates the command clock signal MCLK the level of a pulse of which transitions from a logic low level to a logic high level when the level of a pulse of the inverse clock signal CLKB transitions from a logic low level to a logic high level. The second command clock signal generation circuit 251-3 of the command clock signal generation circuit 251 generates the inverse command clock signal MCLKB the level of a pulse of which transitions from a logic high level to a logic low level when the level of a pulse of the inverse clock signal CLKB transitions from a logic low level to a logic high level.

The second flag signal generation circuit 320 of the even odd sensing circuit 255-1 generates the second even flag signal EV-FL2 the level of which transitions from a logic low level to a logic high level when the level of a pulse of the inverse command clock signal MCLKB transitions from a logic high level to a logic low level.

The first logic circuit 330 of the masking circuit 255-2 generates the first latch clock signal LC-EV having a logic high level when a pulse of the command clock signal MCLK having a logic high level is generated and the first even flag signal EV-FL1 having a logic high level is generated. The first logic circuit 330 generates the second latch clock signal LC-OD having a logic low level when a pulse of the command clock signal MCLK having a logic high level is generated and the first odd flag signal OD-FL1 having a logic low level is generated. The first logic circuit 330 blocks the generation of the second latch clock signal LC-OD when a pulse of the command clock signal MCLK having a logic high level is generated and the first odd flag signal OD-FL1 having a logic low level is generated.

At timing T17, the first command clock signal generation circuit 251-1 of the command clock signal generation circuit 251 generates the command clock signal MCLK the level of a pulse of which transitions from a logic high level to a logic low level when the level of a pulse of the inverse clock signal CLKB transitions from a logic low level to a logic high level. The second command clock signal generation circuit 251-3 of the command clock signal generation circuit 251 generates the inverse command clock signal MCLKB the level of a pulse of which transitions from a logic low level to a logic high level when the level of a pulse of the inverse clock signal CLKB transitions from a logic low level to a logic high level.

The first flag signal generation circuit 310 of the even odd sensing circuit 255-1 generates the first even flag signal EV-FL1 the level of which transitions from a logic high level to a logic low level when the level of a pulse of the command clock signal MCLK transitions from a logic high level to a logic low level. The first flag signal generation circuit 310 generates the first odd flag signal OD-FL1 the level of which transitions from a logic low level to a logic high level when the level of a pulse of the command clock signal MCLK transitions from a logic high level to a logic low level.

The second logic circuit 340 of the masking circuit 255-2 generates the third latch clock signal LCB-EV having a logic high level when a pulse of the inverse command clock signal MCLKB having a logic high level is generated and the second even flag signal EV-FL2 having a logic high level is generated. The second logic circuit 340 generates the fourth latch clock signal LCB-OD having a logic low level when a pulse of the inverse command clock signal MCLKB having a logic high level is generated and the second odd flag signal OD-FL2 having a logic low level is generated. The second logic circuit 340 blocks the generation of the fourth latch clock signal LCB-OD when a pulse of the inverse command clock signal MCLKB having a logic high level is generated and the second odd flag signal OD-FL2 having a logic low level is generated.

At timing T18, the first command clock signal generation circuit 251-1 of the command clock signal generation circuit 251 generates the command clock signal MCLK the level of a pulse of which transitions from a logic low level to a logic high level when the level of a pulse of the inverse clock signal CLKB transitions from a logic low level to a logic high level. The second command clock signal generation circuit 251-3 of the command clock signal generation circuit 251 generates the inverse command clock signal MCLKB the level of a pulse of which transitions from a logic high level to a logic low level when the level of a pulse of the inverse clock signal CLKB transitions from a logic low level to a logic high level.

The second flag signal generation circuit 320 of the even odd sensing circuit 255-1 generates the second even flag signal EV-FL2 the level of which transitions from a logic high level to a logic low level when the pulse of a pulse of the inverse command clock signal MCLKB transitions from a logic high level to a logic low level. The second flag signal generation circuit 320 generates the second odd flag signal OD-FL2 the level of which transitions from a logic low level to a logic high level when the level of a pulse of the inverse command clock signal MCLKB transitions from a logic high level to a logic low level.

The first logic circuit 330 of the masking circuit 255-2 generates the second latch clock signal LC-OD having a logic high level when a pulse of the command clock signal MCLK having a logic high level is generated and the first odd flag signal OD-FL1 having a logic high level is generated. The first logic circuit 330 generates the first latch clock signal LC-EV having a logic low level when a pulse of the command clock signal MCLK having a logic high level is generated and the first even flag signal EV-FL1 having a logic low level is generated. The first logic circuit 330 blocks the generation of the first latch clock signal LC-EV when a pulse of the command clock signal MCLK having a logic high level is generated and the first even flag signal EV-FL1 having a logic low level is generated.

At timing T19, the first command clock signal generation circuit 251-1 of the command clock signal generation circuit 251 generates the command clock signal MCLK the level of a pulse of which transitions from a logic high level to a logic low level when the level of a pulse of the inverse clock signal CLKB transitions from a logic low level to a logic high level. The second command clock signal generation circuit 251-3 of the command clock signal generation circuit 251 generates the inverse command clock signal MCLKB the level of a pulse of which transitions from a logic low level to a logic high level when the level of a pulse of the inverse clock signal CLKB transitions from a logic low level to a logic high level.

The first flag signal generation circuit 310 of the even odd sensing circuit 255-1 generates the first even flag signal EV-FL1 the level of which transitions from a logic low level to a logic high level when the level of a pulse of the command clock signal MCLK transitions from a logic high level to a logic low level. The first flag signal generation circuit 310 generates the first odd flag signal OD-FL1 the level of which transitions from a logic high level to a logic low level when the level of a pulse of the command clock signal MCLK transitions from a logic high level to a logic low level.

The second logic circuit 340 of the masking circuit 255-2 generates the fourth latch clock signal LCB-OD having a logic high level when a pulse of the inverse command clock signal MCLKB having a logic high level is generated and the second odd flag signal OD-FL2 having a logic high level is generated. The second logic circuit 340 generates the third latch clock signal LCB-EV having a logic low level when a pulse of the inverse command clock signal MCLKB having a logic high level is generated and the second even flag signal EV-FL2 having a logic low level is generated. The second logic circuit 340 blocks the generation of the third latch clock signal LCB-EV when a pulse of the inverse command clock signal MCLKB having a logic high level is generated and the second even flag signal EV-FL2 having a logic low level is generated.

An operation of generating the first to eighth transfer command addresses TD1 to TD8 having the second valid data window by increasing the first valid data window of the rising command address CAR and the valid data window of the falling command address CAF based on the first to fourth latch clock signals LC-EV, LC-OD, LCB-EV, and LCB-OD in the interface area is described below with reference to FIG. 12.

At timing T21, the command address input circuit 270 generates the first transfer command address TD1 by latching the rising command address CAR that is input to have the first valid data window in synchronization with the first latch clock signal LC-EV that is generated at a logic high level. The command address input circuit 270 generates the second transfer command address TD2 by latching the falling command address CAF that is input to have the first valid data window in synchronization with the first latch clock signal LC-EV that is generated at a logic high level. The first transfer command address TD1 is generated from the first bit ECA<1> of the external command address. The second transfer command address TD2 is generated from the second bit ECA<2> of the external command address. Timing T21 is set as the same timing as timing T12 in FIG. 11.

At timing T22, the command address input circuit 270 generates the third transfer command address TD3 by latching the rising command address CAR that is input to have the first valid data window in synchronization with the third latch clock signal LCB-EV that is generated at a logic high level. The command address input circuit 270 generates the fourth transfer command address TD4 by latching the falling command address CAF that is input to have the first valid data window in synchronization with the third latch clock signal LCB-EV that is generated at a logic high level. The third transfer command address TD3 is generated from the third bit ECA<3> of the external command address. The fourth transfer command address TD4 is generated from the fourth bit ECA<4> of the external command address. Timing T22 is set as the same timing as timing T13 in FIG. 11.

At timing T23, the command address input circuit 270 generates the fifth transfer command address TD5 by latching the rising command address CAR that is input to have the first valid data window in synchronization with the second latch clock signal LC-OD that is generated at a logic high level. The command address input circuit 270 generates the sixth transfer command address TD6 by latching the falling command address CAF that is input to have the first valid data window in synchronization with the second latch clock signal LC-OD that is generated at a logic high level. The fifth transfer command address TD5 is generated from the fifth bit ECA<5> of the external command address. The sixth transfer command address TD6 is generated from the sixth bit ECA<6> of the external command address. Timing T23 is set as the same timing as timing T14 in FIG. 11.

At timing T24, the command address input circuit 270 generates the seventh transfer command address TD7 by latching the rising command address CAR that is input to have the first valid data window in synchronization with the fourth latch clock signal LCB-OD that is generated at a logic high level. The command address input circuit 270 generates the eighth transfer command address TD8 by latching the falling command address CAF that is input to have the first valid data window in synchronization with the fourth latch clock signal LCB-OD that is generated at a logic high level. The seventh transfer command address TD7 is generated from the seventh bit ECA<7> of the external command address. The eighth transfer command address TD8 is generated from the eighth bit ECA<8> of the external command address. Timing T24 is set as the same timing as timing T15 in FIG. 11.

At timing T25, the command address input circuit 270 generates the first transfer command address TD1 by latching the rising command address CAR that is input to have the first valid data window in synchronization with the first latch clock signal LC-EV that is generated at a logic high level. The command address input circuit 270 generates the second transfer command address TD2 by latching the falling command address CAF that is input to have the first valid data window in synchronization with the first latch clock signal LC-EV that is generated at a logic high level. The first transfer command address TD1 is generated from the ninth bit ECA<9> of the external command address. The second transfer command address TD2 is generated from the tenth bit ECA<10> of the external command address. Timing T25 is set as the same timing as timing T16 in FIG. 11.

At timing T26, the command address input circuit 270 generates the third transfer command address TD3 by latching the rising command address CAR that is input to have the first valid data window in synchronization with the third latch clock signal LCB-EV that is generated at a logic high level. The command address input circuit 270 generates the fourth transfer command address TD4 by latching the falling command address CAF that is input to have the first valid data window in synchronization with the third latch clock signal LCB-EV that is generated at a logic high level. The third transfer command address TD3 is generated from the eleventh bit ECA<11> of the external command address. The fourth transfer command address TD4 is generated from the twelfth bit ECA<12> of the external command address. Timing T26 is set as the same timing as timing T17 in FIG. 11.

At timing T27, the command address input circuit 270 generates the fifth transfer command address TD5 by latching the rising command address CAR that is input to have the first valid data window in synchronization with the second latch clock signal LC-OD that is generated at a logic high level. The command address input circuit 270 generates the sixth transfer command address TD6 by latching the falling command address CAF that is input to have the first valid data window in synchronization with the second latch clock signal LC-OD that is generated at a logic high level. The fifth transfer command address TD5 is generated from the thirteenth bit ECA<13> of the external command address. The sixth transfer command address TD6 is generated from the fourteenth bit ECA<14> of the external command address. Timing T27 is set as the same timing as timing T18 in FIG. 11.

At timing T28, the command address input circuit 270 generates the seventh transfer command address TD7 by latching the rising command address CAR that is input to have the first valid data window in synchronization with the fourth latch clock signal LCB-OD that is generated at a logic high level. The command address input circuit 270 generates the eighth transfer command address TD8 by latching the falling command address CAF that is input to have the first valid data window in synchronization with the fourth latch clock signal LCB-OD that is generated at a logic high level. The seventh transfer command address TD7 is generated from the fifteenth bit ECA<15> of the external command address. The eighth transfer command address TD8 is generated from the sixteenth bit ECA<16> of the external command address. Timing T28 is set as the same timing as timing T19 in FIG. 11.

As illustrated in FIG. 12, the first and second transfer command addresses TD1 and TD2 are generated from timing T21 to timing T25, that is, the second valid data window, and are output to the through via area 290 through the command input and output line MIO. The third and fourth transfer command addresses TD3 and TD4 are generated from timing T22 to timing T26, that is, the second valid data window, and are output to the through via area 290 through the command input and output line MIO. The fifth and sixth transfer command addresses TD5 and TD6 are generated from timing T23 to timing T27, that is, the second valid data window, and are output to the through via area 290 through the command input and output line MIO. The seventh and eighth transfer command addresses TD7 and TD8 are generated from timing T24 to timing T28, that is, the second valid data window, and are output to the through via area 290 through the command input and output line MIO.

As described above, the memory device 17 of the memory system 1 according to an embodiment of the present disclosure can reduce power consumption that is used in a repeater by generating the command address by increasing the valid data window of the command address in the interface area of the base chip 120 having long loading and providing the plurality of core chips with the command address having the increased valid data window without the repeater that transmits the command address. The memory device 17 of the memory system 1 can secure a margin of the latch circuit because the base chip 120 generates the command address by increasing the valid data window of the command address without using a division clock that latches and transmits the command address and provides the plurality of core chips with the command address having the increased valid data window.

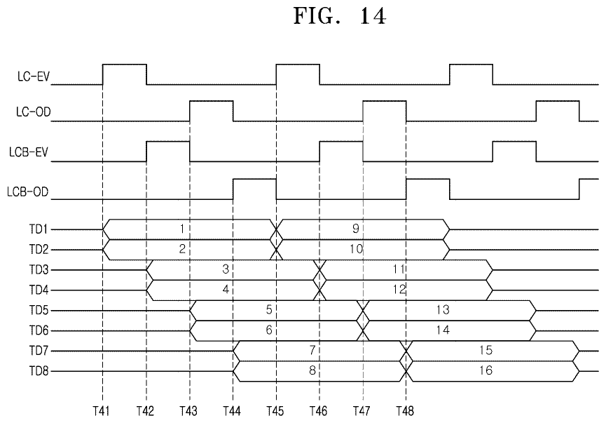

An operation of generating the first to eighth transfer command addresses TD1 to TD8 having the second valid data window by increasing the first valid data window of the rising command address CAR and the valid data window of the falling command address CAF by the clock signal CLK in the interface area of the base chip 120 having long loading according to an embodiment of the present disclosure is described as follows as an example with reference to FIGS. 13 and 14.

First, an operation of generating the first to fourth latch clock signals LC-EV, LC-OD, LCB-EV, and LCB-OD based on a pulse of the clock signal CLK in the interface area is described with reference to FIG. 13.

At timing T31, the first command clock signal generation circuit 251-1 of the command clock signal generation circuit 251 generates the command clock signal MCLK that is initialized as a logic low level (the first logic level) after the start of a power-down operation PD. The second command clock signal generation circuit 251-3 of the command clock signal generation circuit 251 generates the inverse command clock signal MCLKB that is initialized as a logic high level (the second logic level) after the start of the power-down operation PD.

At timing T32, the first command clock signal generation circuit 251-1 of the command clock signal generation circuit 251 generates the command clock signal MCLK the level of a pulse of which transitions from a logic low level to a logic high level when the level of a pulse of the clock signal CLK transitions from a logic low level to a logic high level. The second command clock signal generation circuit 251-3 of the command clock signal generation circuit 251 generates the inverse command clock signal MCLKB the level of a pulse of which transitions from a logic high level to a logic low level when the level of a pulse of the clock signal CLK transitions from a logic low level to a logic high level.

The second flag signal generation circuit 320 of the even odd sensing circuit 255-1 generates the second even flag signal EV-FL2 the level of which transitions from a logic low level to a logic high level when the level of a pulse of the inverse command clock signal MCLKB transitions from a logic high level to a logic low level.

The first logic circuit 330 of the masking circuit 255-2 generates the first latch clock signal LC-EV having a logic high level when a pulse of the command clock signal MCLK having a logic high level is generated and the first even flag signal EV-FL1 having a logic high level is generated. The first logic circuit 330 generates the second latch clock signal LC-OD having a logic low level when a pulse of the command clock signal MCLK having a logic high level is generated and the first odd flag signal OD-FL1 having a logic low level is generated. The first logic circuit 330 blocks the generation of the second latch clock signal LC-OD when a pulse of the command clock signal MCLK having a logic high level is generated and the first odd flag signal OD-FL1 having a logic low level is generated.

At timing T33, the first command clock signal generation circuit 251-1 of the command clock signal generation circuit 251 generates the command clock signal MCLK the level of a pulse of which transitions from a logic high level to a logic low level when the level of a pulse of the clock signal CLK transitions from a logic low level to a logic high level. The second command clock signal generation circuit 251-3 of the command clock signal generation circuit 251 generates the inverse command clock signal MCLKB the level of a pulse of which transitions from a logic low level to a logic high level when the level of a pulse of the clock signal CLK transitions from a logic low level to a logic high level.

The first flag signal generation circuit 310 of the even odd sensing circuit 255-1 generates the first even flag signal EV-FL1 the level of which transitions from a logic high level to a logic low level when the level of a pulse of the command clock signal MCLK transitions from a logic high level to a logic low level. The first flag signal generation circuit 310 generates the first odd flag signal OD-FL1 the level of which transitions from a logic low level to a logic high level when the level of a pulse of the command clock signal MCLK transitions from a logic high level to a logic low level.

The second logic circuit 340 of the masking circuit 255-2 generates the third latch clock signal LCB-EV having a logic high level when a pulse of the inverse command clock signal MCLKB having a logic high level is generated and the second even flag signal EV-FL2 having a logic high level is generated. The second logic circuit 340 generates the fourth latch clock signal LCB-OD having a logic low level when a pulse of the inverse command clock signal MCLKB having a logic high level is generated and the second odd flag signal OD-FL2 having a logic low level is generated. The second logic circuit 340 blocks the generation of the fourth latch clock signal LCB-OD when a pulse of the inverse command clock signal MCLKB having a logic high level is generated and the second odd flag signal OD-FL2 having a logic low level is generated.

At timing T34, the first command clock signal generation circuit 251-1 of the command clock signal generation circuit 251 generates the command clock signal MCLK the level of a pulse of which transitions from a logic low level to a logic high level when the level of a pulse of the clock signal CLK transitions from a logic low level to a logic high level. The second command clock signal generation circuit 251-3 of the command clock signal generation circuit 251 generates the inverse command clock signal MCLKB the level of a pulse of which transitions from a logic high level to a logic low level when the level of a pulse of the clock signal CLK transitions from a logic low level to a logic high level.

The second flag signal generation circuit 320 of the even odd sensing circuit 255-1 generates the second even flag signal EV-FL2 the level of which transitions from a logic high level to a logic low level when the level of a pulse of the inverse command clock signal MCLKB transitions from a logic high level to a logic low level. The second flag signal generation circuit 320 generates the second odd flag signal OD-FL2 the level of which transitions from a logic low level to a logic high level when the level of a pulse of the inverse command clock signal MCLKB transitions from a logic high level to a logic low level.

The first logic circuit 330 of the masking circuit 255-2 generates the second latch clock signal LC-OD having a logic high level when a pulse of the command clock signal MCLK having a logic high level is generated and the first odd flag signal OD-FL1 having a logic high level is generated. The first logic circuit 330 generates the first latch clock signal LC-EV having a logic low level when a pulse of the command clock signal MCLK having a logic high level is generated and the first even flag signal EV-FL1 having a logic low level is generated. The first logic circuit 330 blocks the generation of the first latch clock signal LC-EV when a pulse of the command clock signal MCLK having a logic high level is generated and the first even flag signal EV-FL1 having a logic low level is generated.

At timing T35, the first command clock signal generation circuit 251-1 of the command clock signal generation circuit 251 generates the command clock signal MCLK the level of a pulse of which transitions from a logic high level to a logic low level when the level of a pulse of the clock signal CLK transitions from a logic low level to a logic high level. The second command clock signal generation circuit 251-3 of the command clock signal generation circuit 251 generates the inverse command clock signal MCLKB the level of a pulse of which transitions from a logic low level to a logic high level when the level of a pulse of the clock signal CLK transitions from a logic low level to a logic high level.

The first flag signal generation circuit 310 of the even odd sensing circuit 255-1 generates the first even flag signal EV-FL1 the level of which transitions from a logic low level to a logic high level when the level of a pulse of the command clock signal MCLK transitions from a logic high level to a logic low level. The first flag signal generation circuit 310 generates the first odd flag signal OD-FL1 the level of which transitions from a logic high level to a logic low level when the level of a pulse of the command clock signal MCLK transitions from a logic high level to a logic low level.

The second logic circuit 340 of the masking circuit 255-2 generates the fourth latch clock signal LCB-OD having a logic high level when a pulse of the inverse command clock signal MCLKB having a logic high level is generated and the second odd flag signal OD-FL2 having a logic high level is generated. The second logic circuit 340 generates the third latch clock signal LCB-EV having a logic low level when a pulse of the inverse command clock signal MCLKB having a logic high level is generated and the second even flag signal EV-FL2 having a logic low level is generated. The second logic circuit 340 blocks the generation of the third latch clock signal LCB-EV when a pulse of the inverse command clock signal MCLKB having a logic high level is generated and the second even flag signal EV-FL2 having a logic low level is generated.

At timing T36, the first command clock signal generation circuit 251-1 of the command clock signal generation circuit 251 generates the command clock signal MCLK the level of a pulse of which transitions from a logic low level to a logic high level when the level of a pulse of the clock signal CLK transitions from a logic low level to a logic high level. The second command clock signal generation circuit 251-3 of the command clock signal generation circuit 251 generates the inverse command clock signal MCLKB the level of a pulse of which transitions from a logic high level to a logic low level when the level of a pulse of the clock signal CLK transitions from a logic low level to a logic high level.

The second flag signal generation circuit 320 of the even odd sensing circuit 255-1 generates the second even flag signal EV-FL2 the level of which transitions from a logic low level to a logic high level when the level of a pulse of the inverse command clock signal MCLKB transitions from a logic high level to a logic low level.

The first logic circuit 330 of the masking circuit 255-2 generates the first latch clock signal LC-EV having a logic high level when a pulse of the command clock signal MCLK having a logic high level is generated and the first even flag signal EV-FL1 having a logic high level is generated. The first logic circuit 330 generates the second latch clock signal LC-OD having a logic low level when a pulse of the command clock signal MCLK having a logic high level is generated and the first odd flag signal OD-FL1 having a logic low level is generated. The first logic circuit 330 blocks the generation of the second latch clock signal LC-OD when a pulse of the command clock signal MCLK having a logic high level is generated and the first odd flag signal OD-FL1 having a logic low level is generated.

At timing T37, the first command clock signal generation circuit 251-1 of the command clock signal generation circuit 251 generates the command clock signal MCLK the level of a pulse of which transitions from a logic high level to a logic low level when the level of a pulse of the clock signal CLK transitions from a logic low level to a logic high level. The second command clock signal generation circuit 251-3 of the command clock signal generation circuit 251 generates the inverse command clock signal MCLKB the level of a pulse of which transitions from a logic low level to a logic high level when the level of a pulse of the clock signal CLK transitions from a logic low level to a logic high level.

The first flag signal generation circuit 310 of the even odd sensing circuit 255-1 generates the first even flag signal EV-FL1 the level of which transitions from a logic high level to a logic low level when the level of a pulse of the command clock signal MCLK transitions from a logic high level to a logic low level. The first flag signal generation circuit 310 generates the first odd flag signal OD-FL1 the level of which transitions from a logic low level to a logic high level when the level of a pulse of the command clock signal MCLK transitions from a logic high level to a logic low level.

The second logic circuit 340 of the masking circuit 255-2 generates the third latch clock signal LCB-EV having a logic high level when a pulse of the inverse command clock signal MCLKB having a logic high level is generated and the second even flag signal EV-FL2 having a logic high level is generated. The second logic circuit 340 generates the fourth latch clock signal LCB-OD having a logic low level when a pulse of the inverse command clock signal MCLKB having a logic high level is generated and the second odd flag signal OD-FL2 having a logic low level is generated. The second logic circuit 340 blocks the generation of the fourth latch clock signal LCB-OD when a pulse of the inverse command clock signal MCLKB having a logic high level is generated and the second odd flag signal OD-FL2 having a logic low level is generated.

At timing T38, the first command clock signal generation circuit 251-1 of the command clock signal generation circuit 251 generates the command clock signal MCLK the level of a pulse of which transitions from a logic low level to a logic high level when the level of a pulse of the clock signal CLK transitions from a logic low level to a logic high level. The second command clock signal generation circuit 251-3 of the command clock signal generation circuit 251 generates the inverse command clock signal MCLKB the level of a pulse of which transitions from a logic high level to a logic low level when the level of a pulse of the clock signal CLK transitions from a logic low level to a logic high level.

The second flag signal generation circuit 320 of the even odd sensing circuit 255-1 generates the second even flag signal EV-FL2 the level of which transitions from a logic high level to a logic low level when the level of a pulse of the inverse command clock signal MCLKB transitions from a logic high level to a logic low level. The second flag signal generation circuit 320 generates the second odd flag signal OD-FL2 the level of which transitions from a logic low level to a logic high level when the level of a pulse of the inverse command clock signal MCLKB transitions from a logic high level to a logic low level.

The first logic circuit 330 of the masking circuit 255-2 generates the second latch clock signal LC-OD having a logic high level when a pulse of the command clock signal MCLK having a logic high level is generated and the first odd flag signal OD-FL1 having a logic high level is generated. The first logic circuit 330 generates the first latch clock signal LC-EV having a logic low level when a pulse of the command clock signal MCLK having a logic high level is generated and the first even flag signal EV-FL1 having a logic low level is generated. The first logic circuit 330 blocks the generation of the first latch clock signal LC-EV when a pulse of the command clock signal MCLK having a logic high level is generated and the first even flag signal EV-FL1 having a logic low level is generated.

At timing T39, the first command clock signal generation circuit 251-1 of the command clock signal generation circuit 251 generates the command clock signal MCLK the level of a pulse of which transitions from a logic high level to a logic low level when the level of a pulse of the clock signal CLK transitions from a logic low level to a logic high level. The second command clock signal generation circuit 251-3 of the command clock signal generation circuit 251 generates the inverse command clock signal MCLKB the level of a pulse of which transitions from a logic low level to a logic high level when the level of a pulse of the clock signal CLK transitions from a logic low level to a logic high level.

The first flag signal generation circuit 310 of the even odd sensing circuit 255-1 generates the first even flag signal EV-FL1 the level of which transitions from a logic low level to a logic high level when the level of a pulse of the command clock signal MCLK transitions from a logic high level to a logic low level. The first flag signal generation circuit 310 generates the first odd flag signal OD-FL1 the level of which transitions from a logic high level to a logic low level when the level of a pulse of the command clock signal MCLK transitions from a logic high level to a logic low level.

The second logic circuit 340 of the masking circuit 255-2 generates the fourth latch clock signal LCB-OD having a logic high level when a pulse of the inverse command clock signal MCLKB having a logic high level is generated and the second odd flag signal OD-FL2 having a logic high level is generated. The second logic circuit 340 generates the third latch clock signal LCB-EV having a logic low level when a pulse of the inverse command clock signal MCLKB having a logic high level is generated and the second even flag signal EV-FL2 having a logic low level is generated. The second logic circuit 340 blocks the generation of the third latch clock signal LCB-EV when a pulse of the inverse command clock signal MCLKB having a logic high level is generated and the second even flag signal EV-FL2 having a logic low level is generated.

An operation of generating the first to eighth transfer command addresses TD1 to TD8 having the second valid data window by increasing the first valid data window of the rising command address CAR and the valid data window of the falling command address CAF based on the first to fourth latch clock signals LC-EV, LC-OD, LCB-EV, and LCB-OD in the interface area is described below with reference to FIG. 14.

At timing T41, the command address input circuit 270 generates the first transfer command address TD1 by latching the rising command address CAR that is input to have the first valid data window in synchronization with the first latch clock signal LC-EV that is generated at a logic high level. The command address input circuit 270 generates the second transfer command address TD2 by latching the falling command address CAF that is input to have the first valid data window in synchronization with the first latch clock signal LC-EV that is generated at a logic high level. The first transfer command address TD1 is generated from the first bit ECA<1> of the external command address. The second transfer command address TD2 is generated from the second bit ECA<2> of the external command address. Timing T21 is set as the same timing as timing T12 in FIG. 11.

At timing T42, the command address input circuit 270 generates the third transfer command address TD3 by latching the rising command address CAR that is input to have the first valid data window in synchronization with the third latch clock signal LCB-EV that is generated at a logic high level. The command address input circuit 270 generates the fourth transfer command address TD4 by latching the falling command address CAF that is input to have the first valid data window in synchronization with the third latch clock signal LCB-EV that is generated at a logic high level. The third transfer command address TD3 is generated from the third bit ECA<3> of the external command address. The fourth transfer command address TD4 is generated from the fourth bit ECA<4> of the external command address. Timing T42 is set as the same timing as timing T33 in FIG. 13.

At timing T43, the command address input circuit 270 generates the fifth transfer command address TD5 by latching the rising command address CAR that is input to have the first valid data window in synchronization with the second latch clock signal LC-OD that is generated at a logic high level. The command address input circuit 270 generates the sixth transfer command address TD6 by latching the falling command address CAF that is input to have the first valid data window in synchronization with the second latch clock signal LC-OD that is generated at a logic high level. The fifth transfer command address TD5 is generated from the fifth bit ECA<5> of the external command address. The sixth transfer command address TD6 is generated from the sixth bit ECA<6> of the external command address. Timing T43 is set as the same timing as timing T34 in FIG. 13.

At timing T44, the command address input circuit 270 generates the seventh transfer command address TD7 by latching the rising command address CAR that is input to have the first valid data window in synchronization with the fourth latch clock signal LCB-OD that is generated at a logic high level. The command address input circuit 270 generates the eighth transfer command address TD8 by latching the falling command address CAF that is input to have the first valid data window in synchronization with the fourth latch clock signal LCB-OD that is generated at a logic high level. The seventh transfer command address TD7 is generated from the seventh bit ECA<7> of the external command address. The eighth transfer command address TD8 is generated from the eighth bit ECA<8> of the external command address. Timing T44 is set as the same timing as timing T35 in FIG. 13.

At timing T45, the command address input circuit 270 generates the first transfer command address TD1 by latching the rising command address CAR that is input to have the first valid data window in synchronization with the first latch clock signal LC-EV that is generated at a logic high level. The command address input circuit 270 generates the second transfer command address TD2 by latching the falling command address CAF that is input to have the first valid data window in synchronization with the first latch clock signal LC-EV that is generated at a logic high level. The first transfer command address TD1 is generated from the ninth bit ECA<9> of the external command address. The second transfer command address TD2 is generated from the tenth bit ECA<10> of the external command address. Timing T45 is set as the same timing as timing T36 in FIG. 13.

At timing T46, the command address input circuit 270 generates the third transfer command address TD3 by latching the rising command address CAR that is input to have the first valid data window in synchronization with the third latch clock signal LCB-EV that is generated at a logic high level. The command address input circuit 270 generates the fourth transfer command address TD4 by latching the falling command address CAF that is input to have the first valid data window in synchronization with the third latch clock signal LCB-EV that is generated at a logic high level. The third transfer command address TD3 is generated from the eleventh bit ECA<11> of the external command address. The fourth transfer command address TD4 is generated from the twelfth bit ECA<12> of the external command address. Timing T46 is set as the same timing as timing T37 in FIG. 13.

At timing T47, the command address input circuit 270 generates the fifth transfer command address TD5 by latching the rising command address CAR that is input to have the first valid data window in synchronization with the second latch clock signal LC-OD that is generated at a logic high level. The command address input circuit 270 generates the sixth transfer command address TD6 by latching the falling command address CAF that is input to have the first valid data window in synchronization with the second latch clock signal LC-OD that is generated at a logic high level. The fifth transfer command address TD5 is generated from the thirteenth bit ECA<13> of the external command address. The sixth transfer command address TD6 is generated from the fourteenth bit ECA<14> of the external command address. Timing T47 is set as the same timing as timing T38 in FIG. 13.

At timing T48, the command address input circuit 270 generates the seventh transfer command address TD7 by latching the rising command address CAR that is input to have the first valid data window in synchronization with the fourth latch clock signal LCB-OD that is generated at a logic high level. The command address input circuit 270 generates the eighth transfer command address TD8 by latching the falling command address CAF that is input to have the first valid data window in synchronization with the fourth latch clock signal LCB-OD that is generated at a logic high level. The seventh transfer command address TD7 is generated from the fifteenth bit ECA<15> of the external command address. The eighth transfer command address TD8 is generated from the sixteenth bit ECA<16> of the external command address. Timing T48 is set as the same timing as timing T39 in FIG. 13.

As illustrated in FIG. 14, the first and second transfer command addresses TD1 and TD2 are generated from timing T41 to timing T45, that is, the second valid data window, and are output to the through via area 290 through the command input and output line MIO. The third and fourth transfer command addresses TD3 and TD4 are generated from timing T42 to timing T46, that is, the second valid data window, and are output to the through via area 290 through the command input and output line MIO. The fifth and sixth transfer command addresses TD5 and TD6 are generated from timing T43 to timing T47, that is, the second valid data window, and are output to the through via area 290 through the command input and output line MIO. The seventh and eighth transfer command addresses TD7 and TD8 are generated from timing T44 to timing T48, that is, the second valid data window, and are output to the through via area 290 through the command input and output line MIO.

The memory device 17 of the memory system 1 according to an embodiment of the present disclosure can reduce power consumption that is used in a repeater by generating the command address by increasing the valid data window of the command address in the interface area of the base chip 120 having long loading and providing the plurality of core chips with the command address having the increased valid data window without a repeater that transmits the command address. The memory device 17 of the memory system 1 can secure a margin of the latch circuit because the base chip 120 generates the command address by increasing the valid data window of the command address without using a division clock that latches and transmits the command address and provides the plurality of core chips with the command address having the increased valid data window.

FIG. 15 is a diagram for describing locations at which the interface area PHY and the through via area TSV included in the base chip 120 according to an embodiment of the present disclosure are disposed.

The first through via area 1^{st} TSV may be disposed on the top side TOP of the base chip 120 in a Y axis.

The first through via area 1^{st} TSV may be set as an area including a plurality of through vias. The first through via area 1^{st} TSV may output the first to eighth transfer command addresses TD1 to TD8, that is, the second valid data window, to the plurality of core chips 121-1 to 121-L through the plurality of through vias.

The first interface area 1^{st} PHY may be disposed in a first direction DIR1 on the basis of the first through via area 1^{st} TSV. The first direction DIR1 may be set as a direction that is downward from the top side TOP.

The first interface area 1^{st} PHY may include a first command input and output line MIO1 having long loading. The first interface area 1^{st} PHY may include the clock buffer circuit 210, the address buffer circuit 230, the frequency division circuit 250, and the command address input circuit 270. The command address input circuit 270 may output the first to eighth transfer command addresses TD1 to TD8, that is, the second valid data window, to the first through via area 1^{st} TSV through the first command input and output line MIO1 having long loading.

The second interface area 2^{nd} PHY may be disposed in the first direction DIR1 from the first interface area 1^{st} PHY.

The second interface area 2^{nd} PHY may include a second command input and output line MIO2 having long loading. The second interface area 2nd PHY may include the clock buffer circuit 210, the address buffer circuit 230, the frequency division circuit 250, and the command address input circuit 270. The command address input circuit 270 may output the first to eighth transfer command addresses TD1 to TD8, that is, the second valid data window, to the second through via area 2^{nd} TSV through the second command input and output line MIO2 having long loading.

The second through via area 2^{nd} TSV may be disposed in the first direction DIR1 from the second interface area 2^{nd} PHY.

The second through via area 2^{nd} TSV may be set as an area including a plurality of through vias. The second through via area 2^{nd} TSV may output the first to eighth transfer command addresses TD1 to TD8, that is, the second valid data window, to the plurality of core chips 121-1 to 121-L through the plurality of through vias.

According to an embodiment, the first through via area 1^{st} TSV may be disposed on the bottom side BOTTOM of the base chip 120 in the Y axis. When the first through via area 1^{st} TSV is disposed on the bottom side BOTTOM of the base chip 120 in the Y axis, the first interface area 1^{st} PHY, the second interface area 2^{nd} PHY, and the second through via area 2^{nd} TSV may be sequentially disposed on the basis of the first through via area 1^{st} TSV in a second direction DIR2. The second direction DIR2 may be set as a direction that is upward from the bottom side BOTTOM.

According to an embodiment, the first through via area 1^{st} TSV may be disposed on the left side LEFT of the base chip 120 in an X axis. When the first through via area 1^{st} TSV is disposed on the left side LEFT of the base chip 120 in the X axis, the first interface area 1^{st} PHY, the second interface area 2^{nd} PHY, and the second through via area 2^{nd} TSV may be sequentially disposed in a third direction DIR3 on the basis of the first through via area 1^{st} TSV. The third direction DIR3 may be set as a direction that is rightward from the left side LEFT.

According to an embodiment, the first through via area 1^{st} TSV may be disposed on the right side RIGHT of the base chip 120 in the X axis. When the first through via area 1^{st} TSV is disposed on the right side RIGHT of the base chip 120 in the X axis, the first interface area 1st PHY, the second interface area 2nd PHY and the second through via area 2nd TSV may be sequentially disposed in a fourth direction DIR4 on the basis of the first through via area 1^{st} TSV. The fourth direction DIR4 may be set as a direction that is leftward from the right side RIGHT.

Locations at which the first through via area 1^{st} TSV, the first interface area 1^{st} PHY, the second interface area 2^{nd} PHY, and the second through via area 2^{nd} TSV are disposed may be various according to an embodiment.

As described above, the memory device 17 of the memory system 1 according to an embodiment of the present disclosure can reduce power consumption that is used in a repeater by generating the command address by increasing the valid data window of the command address in the interface area of the base chip 120 having long loading and providing the plurality of core chips with the command address having the increased valid data window without a repeater that transmits the command address. According to an embodiment, the memory device 17 of the memory system 1 can secure a margin of the latch circuit because the base chip 120 generates the command address by increasing the valid data window of the command address without using a division clock that latches and transmits the command address and provides the plurality of core chips with the command address having the increased valid data window.

What is claimed is:

1. A semiconductor chip comprising:
a frequency division circuit configured to generate a plurality of latch clock signals based on a command clock signal and an inverse command clock signal that are generated in synchronization with a clock signal; and
a command address input circuit configured to generate transfer command addresses of a first group having a second valid data window by latching a rising command address and a falling command address that are input to have a first valid data window in synchronization with latch clock signals of a first group, among the plurality of latch clock signals, and configured to generate transfer command addresses of a second group having the second valid data window by latching the rising command address and the falling command address that are input to have the first valid data window in synchronization with latch clock signals of a second group, among the plurality of latch clock signals.

2. The semiconductor chip of claim 1, wherein the transfer command addresses of the first and second groups are output to a through via through a command input and output line.

3. The semiconductor chip of claim 1, wherein the clock signal comprises an inverse clock signal.

4. The semiconductor chip of claim 1, wherein:
the first valid data window is set as a first cycle of the clock signal, and
the second valid data window is set as a fourth cycle of the clock signal.

5. The semiconductor chip of claim 1, wherein:
the frequency division circuit blocks a generation of one latch clock signal, among the latch clock signals of the first group and the latch clock signals of the second group when a pulse of the command clock signal is generated, and
the frequency division circuit blocks a generation of one latch clock signal, among the latch clock signals of the first group and the latch clock signals of the second group, when a pulse of the inverse command clock signal is generated.

6. The semiconductor chip of claim 1, wherein the frequency division circuit comprises:
a command clock signal generation circuit configured to generate the command clock signal and the inverse command clock signal that are generated in synchronization with the clock signal; and
a latch clock signal generation circuit configured to generate the latch clock signals of the first and second groups that are generated based on a pulse of the command clock signal and a pulse of the inverse command clock signal.

7. The semiconductor chip of claim 6, wherein the command clock signal generation circuit comprises:
a first command clock signal generation circuit configured to generate the command clock signal that is initialized as a first logic level by a power-down signal and that toggles in synchronization with the inverse clock signal; and
a second command clock signal generation circuit configured to generate the inverse command clock signal that is initialized as a second logic level by the power-down signal and that toggles in synchronization with the inverse clock signal.

8. The semiconductor chip of claim 7, wherein the first command clock generation circuit comprises:
a first initialization circuit configured to initialize the command clock signal at the first logic level by driving the command clock signal with a ground voltage when the power-down signal is enabled; and
a first flip-flop configured to toggle the command clock signal when the inverse clock signal is generated.

9. The semiconductor chip of claim 7, wherein the second command clock generation circuit comprises:
a second initialization circuit configured to initialize the inverse command clock signal at the second logic level by driving the inverse command clock signal with a power supply voltage when the power-down signal is enabled; and
a second flip-flop configured to toggle the inverse command clock signal when the inverse clock signal is generated.

10. The semiconductor chip of claim 6, wherein the latch clock signal generation circuit comprises:
an even odd sensing circuit configured to generate first and second even flag signals and first and second odd flag signals by detecting timing at which a pulse of the command clock signal and a pulse of the inverse command clock signal are input; and
a masking circuit configured to generate the latch clock signals of the first and second groups based on logic levels of the first and second even flag signals and logic levels of the first and second odd flag signals when a pulse of the command clock signal and a pulse of the inverse command clock signal are generated.

11. The semiconductor chip of claim 10, wherein the even odd sensing circuit comprises:
a first flag signal generation circuit configured to generate the first even flag signal and the first odd flag signal that are generated based on a pulse of the command clock signal; and
a second flag signal generation circuit configured to generate the second even flag signal and the second odd flag signal that are generated based on a pulse of the inverse command clock signal.

12. The semiconductor chip of claim 11, wherein the first flag signal generation circuit comprises:
a first even sensing circuit configured to generate the first even flag signal that toggles when the command clock signal having a first logic level is generated; and
a first odd sensing circuit configured to generate the first odd flag signal that toggles by latching the first even flag signal when the command clock signal having the first logic level is generated.

13. The semiconductor chip of claim 11, wherein the second flag signal generation circuit comprises:
a second even sensing circuit configured to generate the second even flag signal that toggles when the inverse command clock signal having a first logic level is generated; and
a second odd sensing circuit configured to generate the second odd flag signal that toggles by latching the second even flag signal when the inverse command clock signal having the first logic level is generated.

14. The semiconductor chip of claim 10, wherein the masking circuit comprises:
a first logic circuit configured to generate one of the latch clock signals of the first group and generate one of the latch clock signals of the second group based on a logic level of the first even flag signal and a logic level of the first odd flag signal when a pulse of the command clock signal is generated; and
a second logic circuit configured to generate one of the latch clock signals of the first group and generate one of the latch clock signals of the second group based on a logic level of the second even flag signal and a logic level of the second odd flag signal when a pulse of the inverse command clock signal is generated.

15. A memory device comprising:
a base chip configured to generate a rising command address and a falling command address having a first valid data window by latching an external command address in synchronization with a clock signal and an inverse clock signal that are generated from an external clock signal in an interface area, configured to generate a plurality of transfer command addresses having a second valid data window by latching the rising command address and the falling command address in synchronization with a plurality of latch clock signals that are generated based on a pulse of the inverse clock signal, and configured to output the plurality of transfer command addresses to core chips through a through via area,
wherein the core chips output data to the base chip by receiving the plurality of transfer command addresses.

16. The memory device of claim 15, wherein the interface area outputs the plurality of transfer command addresses through a command input and output line having long loading.

17. The memory device of claim 15, wherein the interface area comprises:
a frequency division circuit configured to generate the plurality of latch clock signals that are generated based on a pulse of a command clock signal and a pulse of an inverse command clock signal that are generated in synchronization with the inverse clock signal; and
a command address input circuit configured to generate transfer command addresses of a first group, among the plurality of transfer command addresses having the second valid data window, by latching the rising command address and the falling command address that are input to have the first valid data window in synchronization with latch clock signals of a first group, among the plurality of latch clock signals, and configured to generate transfer command addresses of a second group, among the plurality of transfer command addresses having the second valid data window, by latching the rising command address and the falling command address that are input to have the first valid data window in synchronization with latch clock signals of a second group, among the plurality of latch clock signals.

18. The memory device of claim 17, wherein the frequency division circuit comprises:
a command clock signal generation circuit configured to generate the command clock signal and the inverse command clock signal in synchronization with the inverse clock signal; and
a latch clock signal generation circuit configured to generate the plurality of latch clock signals that are generated based on a pulse of the command clock signal and a pulse of the inverse command clock signal.

19. The memory device of claim 18, wherein the command clock signal generation circuit comprises:
a first command clock signal generation circuit configured to generate the command clock signal that is initialized as a first logic level by a power-down signal and that toggles in synchronization with the inverse clock signal; and
a second command clock signal generation circuit configured to generate the inverse command clock signal that is initialized as a second logic level by the power-down signal and that toggles in synchronization with the inverse clock signal.

20. The memory device of claim 19, wherein the first command clock generation circuit comprises:
a first initialization circuit configured to initialize the command clock signal at the first logic level by driving the command clock signal with a ground voltage when the power-down signal is enabled; and
a first flip-flop configured to toggle the command clock signal when the inverse clock signal is generated.

21. The memory device of claim 19, wherein the second command clock generation circuit comprises:
a second initialization circuit configured to initialize the inverse command clock signal at the second logic level by driving the inverse command clock signal with a power supply voltage when the power-down signal is enabled; and
a second flip-flop configured to toggle the inverse command clock signal when the inverse clock signal is generated.

22. The memory device of claim 18, wherein the latch clock signal generation circuit comprises:
an even odd sensing circuit configured to generate first and second even flag signals and first and second odd flag signals by detecting timing at which a pulse of the command clock signal and a pulse of the inverse command clock signal are input; and
a masking circuit configured to generate the plurality of latch clock signals based on logic levels of the first and second even flag signals and logic levels of the first and second odd flag signals when a pulse of the command clock signal and a pulse of the inverse command clock signal are generated.

23. The memory device of claim 22, wherein the even odd sensing circuit comprises:
a first flag signal generation circuit configured to generate the first even flag signal and the first odd flag signal that are generated based on a pulse of the command clock signal; and
a second flag signal generation circuit configured to generate the second even flag signal and the second odd flag signal that are generated based on a pulse of the inverse command clock signal.

24. The memory device of claim 23, wherein the first flag signal generation circuit comprises:
a first even sensing circuit configured to generate the first even flag signal that toggles when the command clock signal having a first logic level is generated; and
a first odd sensing circuit configured to generate the first odd flag signal that toggles by latching the first even flag signal when the command clock signal having the first logic level is generated.

25. The memory device of claim 23, wherein the second flag signal generation circuit comprises:
a second even sensing circuit configured to generate the second even flag signal that toggles when the inverse command clock signal having a first logic level is generated; and
a second odd sensing circuit configured to generate the second odd flag signal that toggles by latching the second even flag signal when the inverse command clock signal having the first logic level is generated.

26. The memory device of claim 22, wherein the masking circuit comprises:
a first logic circuit configured to generate one of the latch clock signals of the first group and generate one of the latch clock signals of the second group based on a logic level of the first even flag signal and a logic level of the first odd flag signal when a pulse of the command clock signal is generated; and
a second logic circuit configured to generate one of the latch clock signals of the first group and generate one of the latch clock signals of the second group based on a logic level of the second even flag signal and a logic level of the second odd flag signal when a pulse of the inverse command clock signal is generated.
